(19) United States
(12) Patent Application Publication
(10) Pub. No.: US 2026/0082742 A1
(43) Pub. Date: Mar. 19, 2026

(54) SINGLE PHOTON SOURCE DEVICE AND METHOD FOR MANUFACTURING SINGLE PHOTON SOURCE DEVICE

(71) Applicant: BRIGHT QUANTUM INC., Daejeon (KR)

(72) Inventors: Donghan LEE, Daejeon (KR); Yudong JANG, Daejeon (KR); Hyunju AHN, Daejeon (KR)

(73) Assignee: BRIGHT QUANTUM INC., Daejeon (KR)

(21) Appl. No.: 19/393,392

(22) Filed: Nov. 18, 2025

Related U.S. Application Data
(63) Continuation-in-part of application No. 18/615,935, filed on Mar. 25, 2024.

(30) Foreign Application Priority Data
Apr. 5, 2023 (KR) 10-2023-0044820

(51) Int. Cl. H10H 20/856; H10H 20/01; H10H 20/812; H10H 20/824

(52) U.S. Cl. CPC H10H 20/856; H10H 20/01335; H10H 20/0363; H10H 20/812; H10H 20/824

(57) ABSTRACT

A single photon source device is proposed. The device may include a reflection layer including a base portion and a recessed portion having a concave shape that is recessed from the base portion, a single emitter disposed within the recessed portion of the reflection layer and configured to emit a single photon, a solid resonator configured to fill the recessed portion to surround the single emitter, and a solid immersion lens portion disposed on the solid resonator to surround the solid resonator.

### CROSS-REFERENCE TO RELATED APPLICATIONS

This application claims the benefit of U.S. Provisional Patent Application No. 63/806,961 filed on May 16, 2025 and is a continuation-in-part of U.S. patent application Ser. No. 18/615,935 filed on Mar. 25, 2024, which claims priority to Korean Patent Application No. 10-2023-0044820 filed on Apr. 5, 2023, the entire contents of which are herein incorporated by reference.

### TECHNICAL FIELD

The present disclosure relates to a single photon source device and a method of manufacturing the single photon source device.

### BACKGROUND

In quantum information technology, qubits (quantum bits) are created by using single photons and used in application fields such as quantum cryptography communication and quantum computing.

### SUMMARY

One aspect is a single photon source device that simultaneously satisfies a wide operating band and high light collection efficiency, and a method of manufacturing the single photon source device.

Another aspect is a single photon source device that is easy to manufacture and has a good yield and low manufacturing cost, and a method of manufacturing the single photon source device.

An embodiment of the present disclosure provides a single photon source device including a reflection layer including a base portion and a recessed portion having a concave shape that is recessed from the base portion, a single emitter disposed within the recessed portion of the reflection layer and configured to emit a single photon, a solid resonator configured to fill the recessed portion to surround the single emitter, and a solid immersion lens portion disposed on the solid resonator to surround the solid resonator.

In an embodiment of the present disclosure, the single photon source device may further include an insulating layer disposed between the reflection layer and the solid resonator.

In an embodiment of the present disclosure, the insulating layer may be transparent at an emission wavelength of the single emitter.

In an embodiment of the present disclosure, the insulating layer may include an extension portion extending parallel to the base portion from an edge of the recessed portion.

In an embodiment of the present disclosure, one surface of the solid resonator may be located at a same height as one surface of the extension portion.

In an embodiment of the present disclosure, a width of the recessed portion may gradually decrease as a distance from the base portion of the reflection layer increases.

In an embodiment of the present disclosure, a cross section of the recessed portion perpendicular to the base portion may have a trapezoidal shape or a parabolic shape.

In an embodiment of the present disclosure, the solid resonator may include a first surface in direct contact with the solid immersion lens portion, a second surface facing the first surface, and a side surface between the first surface and the second surface, and the side surface of the solid resonator may include a tapered inclined surface.

In an embodiment of the present disclosure, the side surface of the solid resonator may have an inclination angle of 8° to 15° with respect to a line parallel to a central axis of the solid resonator.

In an embodiment of the present disclosure, the single emitter may be spaced apart from the second surface of the solid resonator in a height direction of the single photon source device.

In an embodiment of the present disclosure, a distance between the single emitter and the second surface of the solid resonator may be a distance corresponding to an antinode of a distribution of the single photon emitted from the single emitter.

In an embodiment of the present disclosure, the single emitter may be located within 200 nm from a central axis of the solid resonator.

In an embodiment of the present disclosure, the solid immersion lens portion may have a convex shape protruding from one surface of the solid resonator.

In an embodiment of the present disclosure, a center of a cross section of the solid immersion lens portion on the solid resonator may be located within 500 nm from a virtual line extending from a central axis of the solid resonator.

In an embodiment of the present disclosure, a maximum diameter of the solid immersion lens portion may be greater than a maximum diameter of the solid resonator.

In an embodiment of the present disclosure, a refractive index of the solid immersion lens portion may be smaller than a refractive index of the solid resonator.

In an embodiment of the present disclosure, the single emitter may be a quantum dot.

In an embodiment of the present disclosure, the quantum dot may include one or more of indium arsenide (InAs), indium gallium arsenide (InGaAs), aluminum gallium arsenide (AlGaAs), gallium arsenide (GaAs), and indium phosphide (InP).

An embodiment of the present disclosure provides a method of manufacturing a single photon source device, the method including a quantum dot containing epitaxial layer forming step of forming a quantum dot containing epitaxial layer in which a quantum dot is located, a solid resonator forming step of forming a solid resonator surrounding the quantum dot by removing a portion of the quantum dot containing epitaxial layer, a reflection layer forming step of forming, on the solid resonator, a reflection layer in which a recessed portion corresponding to the solid resonator is formed, and a solid immersion lens portion forming step of forming a solid immersion lens portion facing the reflection layer on the solid resonator.

According to the embodiments of the present disclosure, there is an effect that the single photon source device simultaneously satisfies a wide operating band and high light collection efficiency.

Further, according to the embodiments of the present disclosure, since a structure of the single photon source device is simple, there is effect that the single photon source device is easy to manufacture and has good yield and a low manufacturing cost.

### BRIEF DESCRIPTION OF THE DRAWINGS

FIG. 1 is a partially cut-away perspective view showing a single photon source device according to a first embodiment of the present disclosure.

FIG. 2 is a cross-sectional view of a single photon source device according to a second embodiment of the present disclosure.

FIG. 3 is a diagram illustrating an intensity of an electric field according to an angle with respect to a center of the single photon source device that does not include a second solid immersion lens portion on the single photon source device when single photons are emitted from the single photon source device, and a diagram illustrating an intensity of an electric field according to an angle with respect to a center of the single photon source device that includes the second solid immersion lens portion on the single photon source device when single photons are emitted from the single photon source device.

FIG. 4 shows an image obtained by imaging a first solid immersion lens portion of the single photon source device according to the first embodiment of the present disclosure using a scanning electron microscope (SEM), and a graph showing a thickness of the first solid immersion lens portion according to a distance from a center portion of the first solid immersion lens portion measured using an atomic force microscope (AFM).

FIG. 5 shows a photograph obtained by photographing the second solid immersion lens portion of the single photon source device according to the first embodiment of the present disclosure using the scanning electron microscope.

FIG. 6 is a graph showing change in light collection efficiency according to a wavelength of a single photon emitted from the single photon source device according to the first embodiment of the present disclosure, which is obtained through a simulation.

FIG. 7 is a graph showing light collection efficiency of the single photon source device that does not include the second solid immersion lens portion and light collection efficiency according to a numerical aperture (NA) of the single photon source device that includes the second solid immersion lens portion.

FIG. 8 is a cross-sectional view of a single photon source device according to a second embodiment of the present disclosure.

FIG. 9 is a graph showing that a wavelength of a single photon is changed by the single photon source device according to the second embodiment of the present disclosure.

FIG. 10 is a diagram illustrating a method of manufacturing a single photon source device according to an embodiment of the present disclosure.

FIG. 11 is a process diagram illustrating a step of forming epitaxial layer including a quantum dot in the method of manufacturing single photon source device according to the embodiment of the present disclosure.

FIG. 12 is a process chart showing a step of processing the quantum dot containing epitaxial layer in the method of manufacturing single photon source device according to the embodiment of the present disclosure.

FIG. 13 is a process diagram illustrating a step of forming a first solid immersion lens portion in the method of manufacturing single photon source device according to the embodiment of the present disclosure.

FIG. 14 is a process diagram illustrating a step of forming a second solid immersion lens portion in the method of manufacturing single photon source device according to the embodiment of the present disclosure.

FIG. 15 is a cross-sectional view of a single photon source device according to a third embodiment of the present disclosure.

FIG. 16 is an image obtained by imaging a solid resonator and a solid immersion lens portion of the single photon source device according to the third embodiment of the present disclosure by using a scanning electron microscope.

FIG. 17 is a graph showing a far-field electric field intensity distribution of a single photon source device that does not include a solid immersion lens portion and a far-field electric field intensity distribution of a single photon source device that includes a solid immersion lens portion.

FIG. 18 is a graph showing light collection efficiency according to a side inclination angle of a solid resonator.

FIG. 19 is a graph showing photon extraction efficiency into air (PEEa) according to a wavelength at each side inclination angle of a solid resonator.

FIG. 20 is a graph showing light collection efficiency of a single photon source device that does not include a solid immersion lens portion and light collection efficiency of a single photon source device that includes a solid immersion lens portion.

FIG. 21 is a graph showing single photon signal intensity of a single photon source device that does not include a solid immersion lens portion and single photon signal intensity of a single photon source device that includes a solid immersion lens portion.

FIG. 22 is a cross-sectional view illustrating a modification of the single photon source device of FIG. 15.

FIGS. 23 to 26 are diagrams describing a method of manufacturing the single photon source device of FIG. 15.

FIG. 27 is a cross-sectional view of a single photon source device according to a fourth embodiment of the present disclosure.

FIG. 28 is a graph showing emission intensity according to a wavelength in a single photon source device according to a comparative example and a single photon source device according to the fourth embodiment of the present disclosure.

FIG. 29 is a graph showing emission intensity according to power of excitation light in the single photon source device according to the comparative example and the single photon source device according to the fourth embodiment of the present disclosure.

FIG. 30 is a cross-sectional view of a single photon source device according to a fifth embodiment of the present disclosure.

### DETAILED DESCRIPTION

Single photon sources that emit single photons can be divided into a light source based on a single emitter and a light source based on a non-linear optical phenomenon, and the light sources based on a single emitter include atom/ion trap, solid-based defect/color center, two-dimensional material, a semiconductor quantum dot, and the like.

Among the light sources based on a single emitter, a semiconductor quantum dot single photon source is a single photon source that can generate single photons on demand and has a high purity of single photons. Semiconductor quantum dot is a three-dimensional isolated structures made of materials with different bandgap energies, with carriers energetically bound, is called an artificial atom because of formation of discontinuous energy levels, and is able to generate single photons through recombination of formed excitons.

Because the single photons emitted from the quantum dot are difficult to escape into the air, the semiconductor quantum dot single photon source requires a light collection structure that can increase light collection efficiency. High efficiency light collection structures that can be used in the semiconductor quantum dot single photon source known to date include a micro-pillar light collection structure, a bull's eye light collection structure, and the like. Since such light collection structures have a characteristic of a narrow operating band, it is very difficult to match an emission wavelength of the quantum dot with a resonance wavelength of the light collection structures, and it is also difficult to manufacture. Further, the light collection structure with a wide operating band is very difficult to manufacture or has low light collection efficiency.

Therefore, there is a need for a light collection structure for a single emitter single photon source that is relatively easy to manufacture while simultaneously satisfying a wide operating band and high light collection efficiency.

Hereinafter, specific embodiments for implementing a spirit of the present disclosure will be described in detail with reference to the drawings.

In describing the present disclosure, detailed descriptions of known configurations or functions may be omitted to clarify the present disclosure.

When an element is referred to as being ‘connected’ to, ‘supported’ by, ‘accessed’ to, ‘supplied’ to, ‘transferred’ to, or ‘contacted’ with another element, it should be understood that the element may be directly connected to, supported by, accessed to, supplied to, transferred to, or contacted with another element, but that other elements may exist in the middle.

The terms used in the present disclosure are only used for describing specific embodiments, and are not intended to limit the present disclosure. Singular expressions include plural expressions unless the context clearly indicates otherwise.

Further, in the present disclosure, it is to be noted that expressions, such as a radial direction, an upper side and a lower side, and a height direction are described based on the illustration of drawings, but may be modified if directions of corresponding objects are changed. For the same reasons, some components are exaggerated, omitted, or schematically illustrated in the accompanying drawings, and the size of each component does not fully reflect the actual size.

Terms including ordinal numbers, such as first and second, may be used for describing various elements, but the corresponding elements are not limited by these terms. These terms are only used for the purpose of distinguishing one element from another element.

In the present specification, it is to be understood that the terms such as “including” are intended to indicate the existence of the certain features, areas, integers, steps, actions, elements, combinations, and/or groups thereof disclosed in the specification, and are not intended to preclude the possibility that one or more other certain features, areas, integers, steps, actions, elements, combinations, and/or groups thereof may exist or may be added.

### Single Photon Source Device

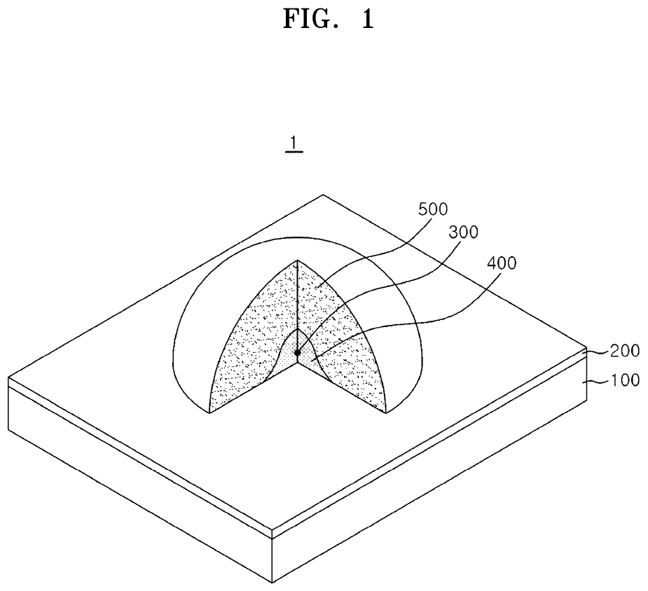

Hereinafter, a specific configuration of a single photon source device 1 according to a first embodiment of the present disclosure will be described with reference to FIGS. 1 to 6.

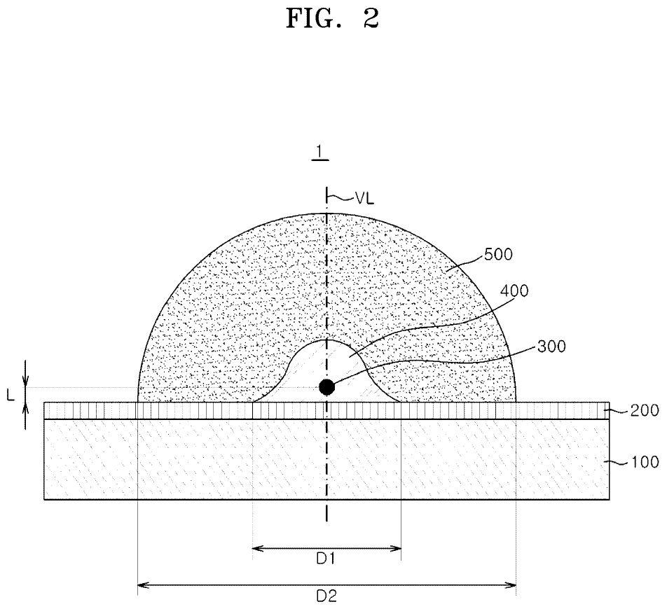

The single photon source device 1 according to the first embodiment of the present disclosure emits a single photon (not shown). The single photon source device 1 allows single photons emitted from a single emitter 300 to be concentrated through a first solid immersion lens portion 400 and a second solid immersion lens portion 500. Due to the collection of the first solid immersion lens portion 400 and the second solid immersion lens portion 500, the single photons may be emitted from the single photon source device 1 in a height direction of the single photon source device 1 in a center portion of the single photon source device 1. Accordingly, the single photon source device 1 may have relatively high light collection efficiency. Further, the single photon source device 1 may have a wide operating band. In other words, the single photon source device 1 may have a relatively wide available wavelength band of the single photons emitted with a predetermined brightness or more. Since the single photon source device 1 has a simple structure, the single photon source device 1 is easy to manufacture and has a good yield and low manufacturing cost. Referring to FIGS. 1 and 2, the single photon source device 1 according to the first embodiment of the present disclosure may include a reflection layer 100, an insulating layer 200, a single emitter 300, a first solid immersion lens portion 400, and a second solid immersion lens portion 500.

The reflection layer 100 may reflect single photons that are emitted from the single emitter 300. The reflection layer 100 may be disposed beneath the insulating layer 200. Accordingly, the single emitter 300 spaced apart from the insulating layer 200 in a direction opposite to the reflection layer 100 may be located above the reflection layer 100. Further, in the single emitter 300, the single photons may be emitted around the single emitter 300 with the single emitter 300 as a center. In other words, the single photons may be emitted in a radial direction from the single emitter 300. In addition, among the single photons emitted from the single emitter 300, the single photons traveling under the single emitter 300 may be reflected by the reflection layer 100 and travel above the single emitter 300. In other words, the single photons emitted from the single emitter 300 and traveling under the single emitter 300 may be reflected by the reflection layer 100 and travel above the single emitter 300. Due to the reflection of the single photons in the reflection layer 100, most of the single photons emitted from the single emitter 300 can pass through the first solid immersion lens portion 400 and travel into the second solid immersion lens portion 500. The reflection layer 100 may include one or more of gold (Au), silver (Ag), aluminum (Al), copper (Cu), and a distributed Bragg reflector (DBR).

The insulating layer 200 may insulate the reflection layer 100. Further, the single emitter 300 is spaced apart from the insulating layer 200 and located inside the first solid immersion lens portion 400, thereby minimizing an influence of a resistance loss caused by the reflection layer 100 applied to the single emitter 300. This insulating layer 200 makes it possible for emission of the single photons from the single emitter 300 to be smoothly performed without being affected by the reflection layer 100. The insulating layer 200 may be disposed on the reflection layer 100. The insulating layer 200 may be transparent at an emission wavelength of the single emitter 300. Therefore, the insulating layer 200 allows the single photons emitted from the single emitter 300 and traveling under the single emitter 300 to pass through the insulating layer 200 and reach the reflection layer 100 while insulating the reflection layer 100. The insulating layer 200 may include one or more of silicon nitride (SiN), silicon oxide (SiO2), aluminum oxide (Al2O3), aluminum nitride (AlN), titanium oxide (TiO2), hafnium oxide (HfO2), and zirconium oxide (ZnO).

The single emitter 300 may emit single photons. When the single emitter 300 is irradiated with light such as a laser having a predetermined wavelength, single photons determined by a structure of the single emitter 300 may be emitted from the single emitter 300.

The single emitter 300 may be a quantum dot. The quantum dot may include a semiconductor. When the quantum dot includes the semiconductor, the quantum dot may include one or more of indium arsenide (InAs), indium gallium arsenide (InGaAs), aluminum gallium arsenide (AlGaAs), gallium arsenide (GaAs), and indium phosphide (InP). The quantum dot may be formed by stacking various types of semiconductors, as will be described later.

The single emitter 300 may include one or more of a solid point defect and a single molecule. The solid point defect may include any one of a nitrogen-vacancy center and a silicon-vacancy center.

The single emitter 300 may be located inside the first solid immersion lens portion 400 so that the single emitter 300 is spaced apart from the insulating layer 200 in the height direction of the single photon source device 1. Further, the single emitter 300 may pass through a center of a cross section of the first solid immersion lens portion 400 above the insulating layer 200, and be located within 200 nm in a radial direction perpendicular to a virtual line VL extending in the height direction of the single photon source device 1 from the virtual line VL. When the single emitter 300 is located outside 200 nm in the radial direction perpendicular to the above-described virtual line VL from the virtual line VL, emission efficiency may decrease. Further, a distance L between the single emitter 300 and the insulating layer 200 may be a distance corresponding to an antinode of a distribution of single photons emitted from the single emitter 300. With this configuration, most of the single photons emitted from the single emitter 300 and the single photons emitted from the single emitter 300 and reflected by the reflection layer 100 may pass through the first solid immersion lens portion 400 to travel to the second solid immersion lens portion 500.

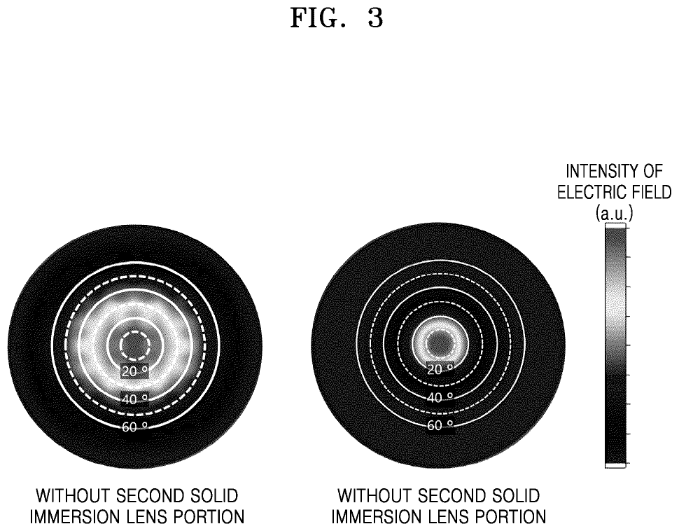

The first solid immersion lens portion 400 allows the single photons emitted from the single emitter 300 and the single photons emitted from the single emitter 300 and reflected by the reflection layer 100 to pass through the first solid immersion lens portion 400 to travel to the second solid immersion lens portion 500. Further, the first solid immersion lens portion 400 may form an optical mode so that the single photons emitted from the single emitter 300 and the single photons emitted from the single emitter 300 and reflected by the reflection layer 100 are primarily directed to around the height direction. Through the concentration of the single photons in the first solid immersion lens portion 400, the single photons emitted from the single emitter 300 and the single photons emitted from the single emitter 300 and reflected by the reflection layer 100 may be concentrated to some extent in the center portion of the first solid immersion lens portion 400 and travel to the second solid immersion lens portion 500. It can be seen from a drawing on the left side of FIG. 3 that the single photons emitted from the single emitter 300 and the single photons emitted from the single emitter 300 and reflected by the reflection layer 100 are concentrated to some extent to the center portion of the far-field radiation pattern.

There is a method in which the single emitter 300 is located in a single mode structure having a diameter as small as 200 nm so that only one light mode is allowed, and most of photons emitted from the single emitter 300 travel in only one direction in a single mode. However, it is difficult to dispose the single emitter 300 at a center of the single mode structure. Therefore, with the above-described method, it is difficult to cause most of the photons emitted from the single emitter 300 to travel in only one direction in the single mode. In other words, it is difficult for only single photons emitted in the height direction of the single photon source device 1 from the center portion of the single photon source device 1 to be emitted from the single emitter 300. However, in the present disclosure, even when single photons are emitted in a multi-mode from the single emitter 300, a mode of the single photons may mainly be a mode in which the single photons are emitted in the height direction of the single photon source device 1 from the center portion of the single photon source device 1 by the first solid immersion lens portion 400. In other words, in the present disclosure, the single emitter 300 needs not to be located at the center of the single mode structure having a diameter as small as 200 nm. Therefore, in the present disclosure, it can be easily realized that only the single photons emitted in the height direction of the single photon source device 1 from the center of the single photon source device 1 are emitted from the single emitter 300.

The first solid immersion lens portion 400 may be disposed on the insulating layer 200 to surround the single emitter 300. Further, the first solid immersion lens portion 400 may have a convex shape that protrudes from the insulating layer 200. The first solid immersion lens portion 400 may include a semiconductor. When the first solid immersion lens portion 400 includes the semiconductor, the first solid immersion lens portion 400 may include one or more of gallium arsenide (GaAs), aluminum gallium arsenide (AlGaAs), gallium indium phosphide (GaInP), indium gallium arsenide (InGaAs), aluminum indium gallium arsenide (AlInGaAs), indium phosphide (InP), and indium gallium arsenide phosphide (InGaAsP). In a case where the single emitter 300 is a quantum dot, the first solid immersion lens portion 400 may be formed by stacking several types of semiconductors to form a quantum dot and then wet-etching a layer where the quantum dot is located, as will be described later.

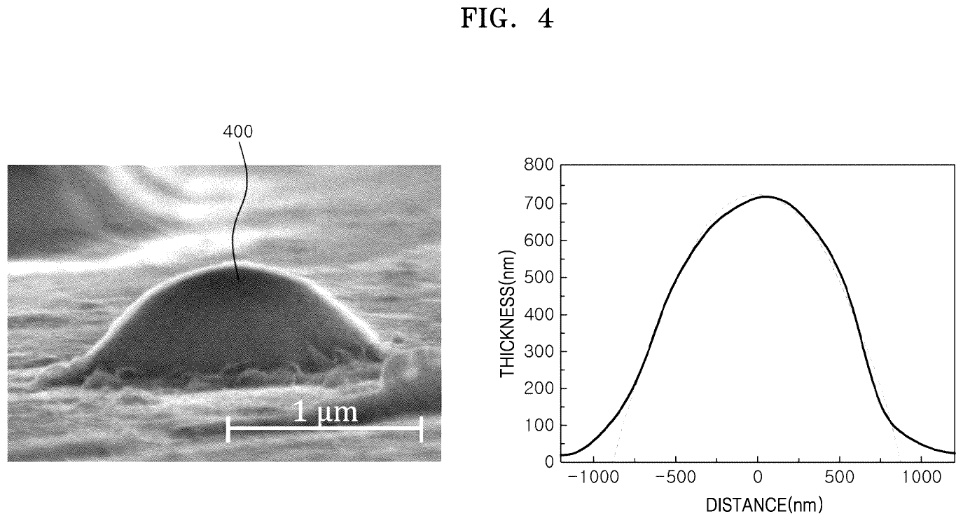

Referring to FIGS. 2 and 4, the first solid immersion lens portion 400 on the insulating layer 200 may have a diameter D1 of about 400 nm to 2000 nm, and a thickness, that is, a height of about 200 nm to 2000 nm. When the diameter D1 of the first solid immersion lens portion 400 on the insulating layer 200 is smaller than 400 nm, manufacturing may be difficult by photolithography. Further, when the diameter D1 of the first solid immersion lens portion 400 on the insulating layer 200 is greater than 2000 nm, emission efficiency may decrease. Further, when the height of the first solid immersion lens portion 400 on the insulating layer 200 is smaller than 200 nm and greater than 2000 nm, the emission efficiency may decrease. A refractive index of the first solid immersion lens portion 400 may be 1.8 to 4.0. When the refractive index of the first solid immersion lens portion 400 is smaller than 1.8, the emission efficiency may decrease. Further, when the refractive index of the first solid immersion lens portion 400 is greater than 4.0, there may be sensitivity to a manufacturing error.

The second solid immersion lens portion 500 may allow the single photons passing through the first solid immersion lens portion 400 to be secondarily directed to the height direction and thus better-collected. Due to the secondary collection of the single photons passing through the second solid immersion lens portion 500, most of the single photons may be emitted in the height direction of the single photon source device 1 from the center of the single photon source device 1. In other words, the single photons may be emitted with directivity from the center of the single photon source device 1. It can be seen from a drawing on the right side of FIG. 3 that the single photons are emitted in the height direction of the single photon source device 1 from the second solid immersion lens portion 500 and thus are further concentrated to the center portion of the far-field radiation pattern.

The second solid immersion lens portion 500 may be disposed on the insulating layer 200 to surround the first solid immersion lens portion 400. Further, the second solid immersion lens portion 500 may have a convex shape that protrudes from the insulating layer 200. The second solid immersion lens portion 500 may include one or both of a polymer and a dielectric. The polymer included in the second solid immersion lens portion 500 may be photoresist. The polymer photoresist included in the second solid immersion lens portion 500 may include one or more of an AZ5200 series photoresist, a PMMA series electron beam resist, and an S1800 series photoresist. Meanwhile, the polymer included in the second solid immersion lens portion 500 may be an electron beam resist. The dielectric included in the second solid immersion lens portion 500 may include one or more of silicon nitride, silicon oxide, aluminum oxide, aluminum nitride, titanium oxide, hafnium oxide, magnesium oxide (MgO), and zirconium oxide.

A refractive index of the second solid immersion lens portion 500 may be smaller than that of the first solid immersion lens portion 400. Since the refractive index of the second solid immersion lens portion 500 is smaller than that of the first solid immersion lens portion 400, a light emission direction of the single photon can be directed in the height direction of the single photon source device 1 without hardly changing the optical mode in the first solid immersion lens portion 400. Further, an operating bandwidth of the single emitter 300 may be widened. The refractive index of the second solid immersion lens portion 500 may be 1.2 to 2.5. When the refractive index of the second solid immersion lens portion 500 is smaller than 1.2, vertical orientation adjustment may be difficult. Further, when the refractive index of the second solid immersion lens portion 500 is greater than 2.5, a non-negligible resonance effect occurs in the second solid immersion lens portion 500, making it difficult to secure better vertical directionality.

The second solid immersion lens portion 500 may be formed by coating, exposing, developing, and reflowing a photoresist. In the reflowing, heat may be applied to the photoresist remaining after development for fluidity, so that the photoresist remaining after development becomes the second solid immersion lens portion 500. A center of a cross section of the second solid immersion lens portion 500 on the insulating layer 200 may pass through a center of a cross section of the first solid immersion lens portion 400 on the insulating layer 200, and be located within 500 nm in a radial direction perpendicular to the virtual line VL extending in the height direction of the single photon source device 1 from the virtual line VL. Therefore, some of the single photons emitted from the single emitter 300 located within the first solid immersion lens portion 400 and the single photons emitted from the single emitter 300 and reflected by the reflection layer 100 may pass through the first solid immersion lens portion 400 and travel to the second solid immersion lens portion 500. When the center of the cross section of the second solid immersion lens portion 500 on the insulating layer 200 is located outside 500 nm in the radial direction perpendicular to the above-described virtual line VL from the virtual line VL, the emission efficiency can decrease.

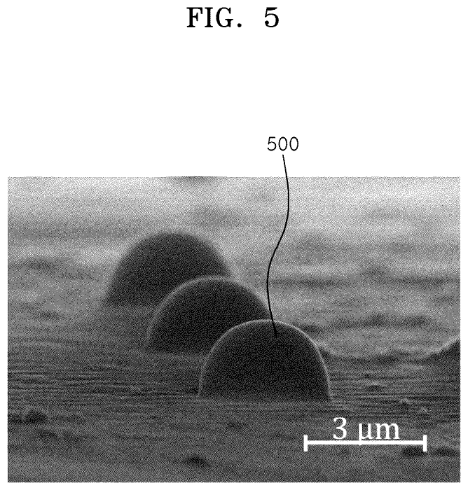

Referring to FIGS. 2 and 5, the second solid immersion lens portion 500 on the insulating layer 200 may have a diameter D2 of about 1 μm to 10 μm, and a thickness of about 1 μm to 10 μm. When the diameter D2 of the second solid immersion lens portion 500 on the insulating layer 200 is smaller than 1 μm or larger than 10 μm, the emission efficiency may decrease. Further, when a height of the second solid immersion lens portion 500 on the insulating layer 200 is smaller than 1 μm and greater than 10 μm, the emission efficiency may decrease.

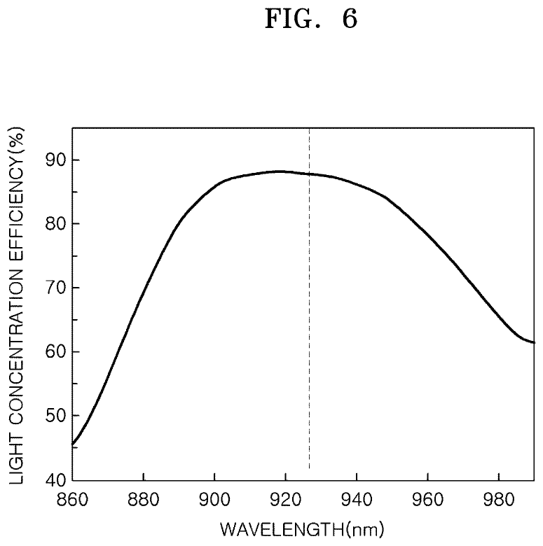

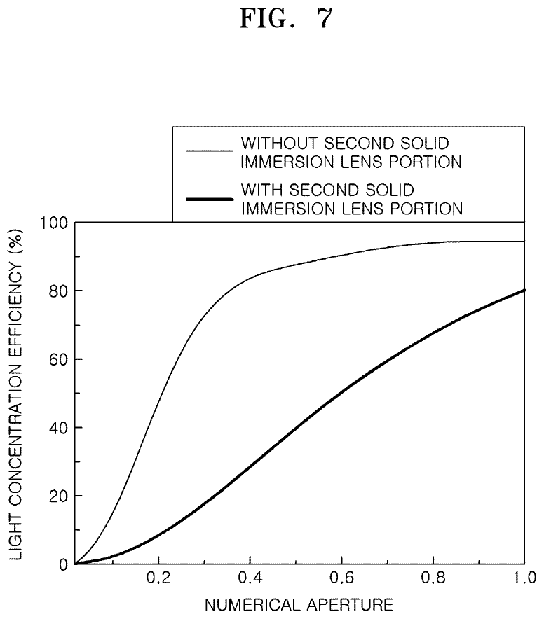

It can be seen from FIG. 6 that the single photon source device 1 having the above-described configuration concentrates 80% or more of single photons in a wavelength range of 890 nm to 960 nm. In other words, it can be seen that 80% or more of the photons are collected at a bandwidth of about 70 nm. Therefore, the single photon source device 1 can simultaneously satisfy a wide operating band and high light collection efficiency. Further, it can be seen from FIG. 7 that, when the single photon source device 1 includes the second solid immersion lens portion 500, the light collection efficiency is improved.

With this single photon source device 1, it is possible to generate single photons with high indistinguishability. When a laser having an emission wavelength matched with that of the single emitter 300 is used to excite the single photon source device 1, it is possible to generate single photons with high indistinguishability. In other words, resonant excitation can be used to obtain the single photons with high indistinguishability from the single photon source device 1. Further, it is possible to generate single photons with high indistinguishability even when a laser having a wavelength close to the emission wavelength of the single emitter 300 is used to excite the single photon source device 1. In other words, quasi-resonant excitation can be used to obtain the single photons with high indistinguishability from the single photon source device 1. Examples of the quasi-resonant excitation may include p-shell pumping or phonon-assisted pumping.

Meanwhile, according to a second embodiment of the present disclosure, the single photon source device 1 may further include a substrate 600 and a piezoelectric substrate 700, in addition to this configuration.

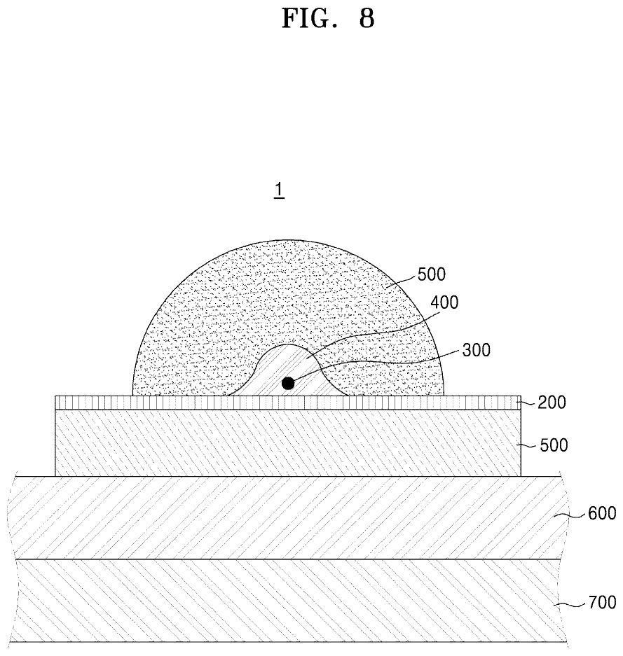

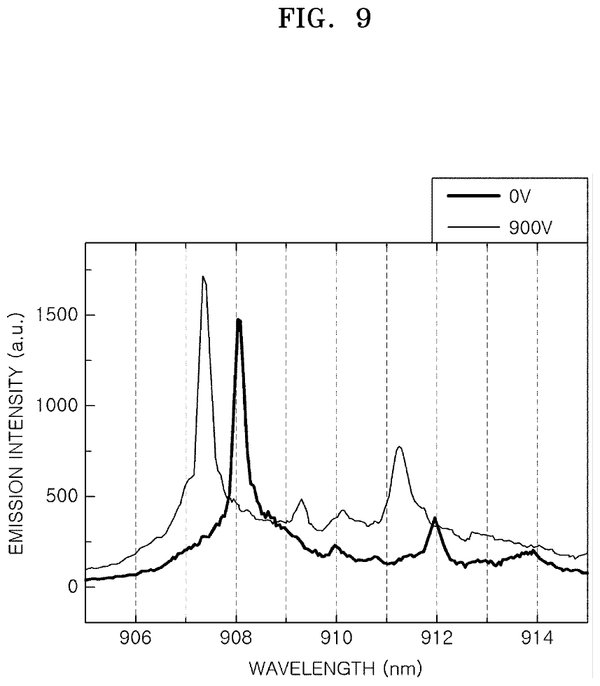

Hereinafter, the second embodiment will be described with reference to FIGS. 8 and 9. The second embodiment of the present disclosure is different from the first embodiment described above, is that the single photon source device 1 further includes the substrate 600 and the piezoelectric substrate 700, this difference will be mainly described, and the same description and reference numerals as those in the above-described embodiments will be used.

Referring to FIG. 8, according to the second embodiment of the present disclosure, the single photon source device 1 may further include the substrate 600 and the piezoelectric substrate 700.

The substrate 600 may support the reflection layer 100. The substrate 600 may include one or more of silicon (Si), gallium arsenide (GaAs), indium phosphide (InP), aluminum arsenide (AlAs), silicon oxide (SiO2), aluminum oxide (Al2O3), and silicon nitride (SiN). The substrate 600 may be bonded directly to the reflection layer 100 to support the reflection layer 100, or may be bonded to the reflection layer 100 using an adhesive containing epoxy to support the reflection layer 100.

The substrate 600 may be disposed on the piezoelectric substrate 700. The piezoelectric substrate 700 may include one or more of a lead zirconate titanate (PZT) series and a lead magnesium niobate-lead titanate (PMN-PT) series. The piezoelectric substrate 700 may be connected to a power supply. Further, when a voltage is applied to the piezoelectric substrate 700 by the power supply, strain may occur in the piezoelectric substrate 700. Further, a wavelength of the single photons emitted from the single emitter 300 may be changed through transfer of the strain occurring in the piezoelectric substrate 700.

It can be seen from FIG. 9 that, when a voltage of 900 V is applied to the piezoelectric substrate 700, the wavelength of the single photons emitted from the single emitter 300 is changed.

Further, when the voltage is applied to the piezoelectric substrate 700 by the power supply, strain occurs in the piezoelectric substrate 700, and a fine structure splitting can be adjusted to a minimum through transfer of the strain so that entangled photon pairs can be generated.

Meanwhile, the reflection layer 100 may be disposed on the piezoelectric substrate 700 without the substrate 600.

### Method of Manufacturing Single Photon Source Device

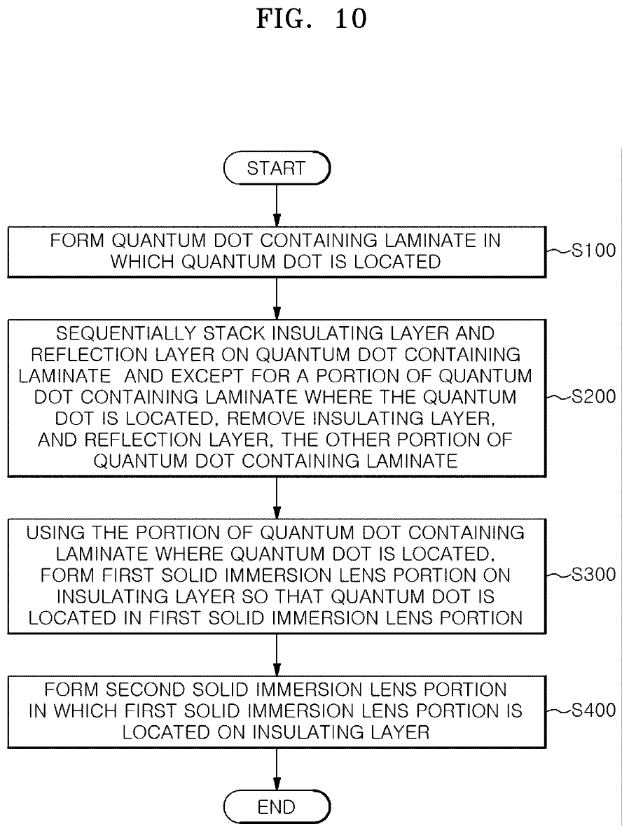

Hereinafter, a specific configuration of a method of manufacturing the single photon source device according to an embodiment of the present disclosure will be described with reference to FIGS. 10 to 14.

With the method of manufacturing single photon source device according to an embodiment of the present disclosure, the single photon source device 1 in which the single emitter 300 is a quantum dot can be manufactured. In the method of manufacturing single photon source device, it is not easy to use an electron beam lithography, a dry etching equipment, or the like, and the single photon source device 1 can be manufactured without using expensive devices. In addition, with the method of manufacturing single photon source device, it is possible to easily manufacture the single photon source device 1 with a good yield and low fabricating cost. Referring to FIG. 10, the method of manufacturing single photon source device may include forming a quantum dot containing epitaxial layer (S100), processing the quantum dot containing epitaxial layer (S200), forming a first solid immersion lens portion (S300), and forming a second solid immersion lens portion (S400).

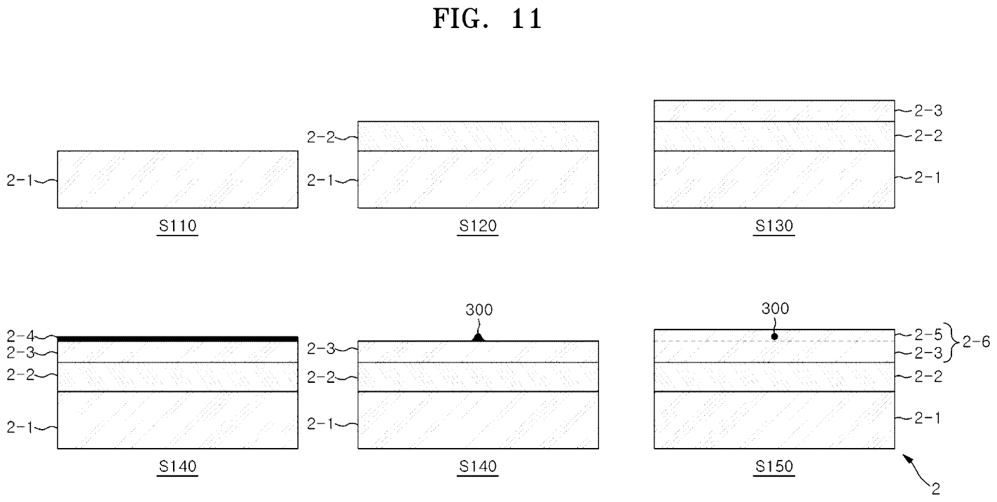

In the forming the quantum dot containing epitaxial layer (S100), a epitaxial layer 2 with quantum dot located therein as the single emitter 300 may be formed. Referring to FIG. 11, the forming the quantum dot containing epitaxial layer (S100) may include a first epitaxial layer layer preparation step (S110), a second epitaxial layer layer stacking step (S120), a third epitaxial layer stacking step (S130), a quantum dot forming layer stacking step (S140), and a quantum dot application step (S150).

In the first epitaxial layer preparation step (S110), a first epitaxial layer 2-1 may be prepared. The first epitaxial layer 2-1 may be a substrate. Further, the first epitaxial layer 2-1 may include one or more of gallium arsenide, indium gallium arsenide, gallium indium phosphide, aluminum gallium arsenide, aluminum arsenide, and indium phosphide. In other words, the first layer 2-1 may be a substrate containing one or more of gallium arsenide, indium arsenide, indium gallium arsenide, aluminum arsenide, and indium phosphide.

In the second epitaxial layer stacking step (S120), a second epitaxial layer 2-2 may be stacked on the first epitaxial layer 2-1. The second epitaxial layer 2-2 may include one or more of aluminum arsenide, aluminum gallium arsenide, gallium arsenide, aluminum indium gallium arsenide (AlINGaAs), indium gallium arsenide, indium gallium phosphide (InGaP), and indium gallium arsenide phosphide. The second epitaxial layer 2-2 may be stacked on the first epitaxial layer 2-1 by molecular-beam epitaxy or metal organic chemical vapor deposition.

In the third epitaxial layer stacking step (S130), the third epitaxial layer 2-3 may be stacked on the second epitaxial layer 2-2. The third epitaxial layer 2-2 may include one or more of gallium arsenide, indium arsenide, indium gallium arsenide, aluminum arsenide, indium gallium arsenide phosphide, aluminum indium gallium arsenide, and indium phosphide. The third epitaxial layer 2-3 may be stacked on the second epitaxial layer 2-2 by molecular beam crystal growth or organic metal chemical vapor deposition.

In the quantum dot forming layer stacking step (S140), a quantum dot forming layer 2-4 may be stacked on the third epitaxial layer 2-3. The quantum dot forming layer 2-4 may include one or more of indium arsenide, indium gallium arsenide, gallium arsenide, indium gallium arsenide phosphide, and indium phosphide. The quantum dot forming layer 2-4 may be stacked on the third epitaxial layer 2-3 by molecular beam crystal growth or organic metal chemical vapor deposition. The quantum dot may be formed as the single emitter 300 on the third epitaxial layer 2-3 by stacking the quantum dot forming layer 2-4 on the third epitaxial layer 2-3.

In the quantum dot application step (S150), a quantum dot application layer 2-5 is stacked on the third epitaxial layer 2-3 so that the quantum dot, which is single emitters 300, is applied by the quantum dot application layer 2-5. The quantum dot application layer 2-5 may include one or more of gallium arsenide, indium arsenide, indium gallium arsenide, aluminum arsenide, indium gallium arsenide phosphide, and indium phosphide. The quantum dot application layer 2-5 may be stacked on the third epitaxial layer 2-3 by molecular beam crystal growth or organic metal chemical vapor deposition. The quantum dot, which is the single emitter 300, can be protected from the outside by the quantum dot application layer 2-5. Further, the third epitaxial layer 2-3 and the quantum dot application layer 2-5 may be combined to form a quantum dot layer 2-6 in which the quantum dot that is the single emitter 300 is located. In addition, a distance L between the quantum dot, which is the single emitter 300, and the insulating layer 200 can be adjusted through adjustment of a thickness of the quantum dot application layer 2-5.

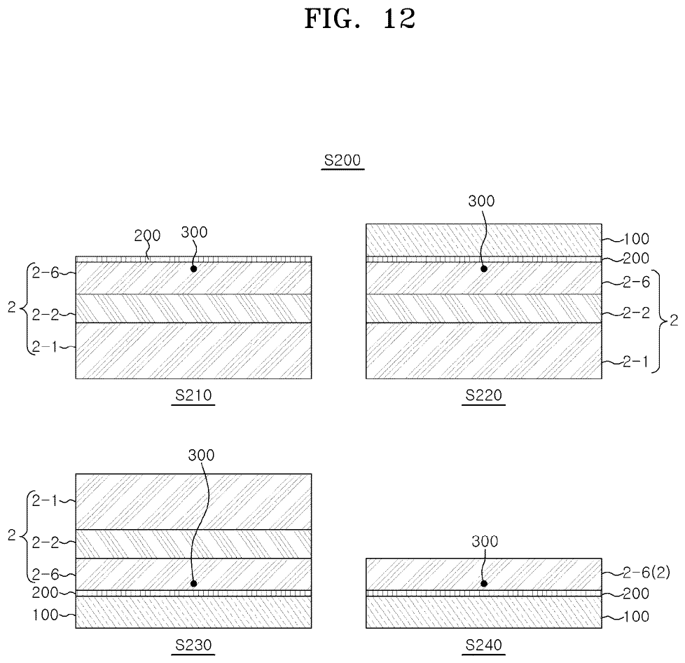

Referring to FIG. 12, in the processing the quantum dot containing epitaxial layer (S200), the insulating layer 200 and the reflection layer 100 may be sequentially stacked on the epitaxial layer 2 including quantum dot. Further, a portion of the epitaxial layer 2 where the quantum dot, which is the single emitter 300, is located, the insulating layer 200, and portions of the epitaxial layer 2 other than the reflection layer 100 may be removed. The processing the quantum dot containing epitaxial layer (S200) may include an insulating layer stacking step (S210), a reflection layer stacking step (S220), a flipping step (S230), and a layer removal step (S240).

In the insulating layer stacking step (S210), the insulating layer 200 may be stacked on the quantum dot layer 2-6 of the epitaxial layer 2. The insulating layer 200 may include one or more of silicon nitride, silicon oxide, aluminum oxide, aluminum nitride, titanium oxide, hafnium oxide, and zirconium oxide. The insulating layer 200 may be stacked on the quantum dot layers 2-6 of the epitaxial layer 2 by sputtering, electron beam deposition, or plasma enhanced chemical vapor deposition (PECVD).

In the reflection layer stacking step (S220), the reflection layer 100 may be stacked on the insulating layer 200. The reflection layer 100 may include one or more of gold, silver, aluminum, copper, and a distributed Bragg reflector. For example, the reflection layer 100 containing gold may be stacked on the insulating layer 200 by sputtering or electron beam deposition.

In the flipping step (S230), the epitaxial layer 2 can be flipped over so that the reflection layer 100 is located at a bottom. In the flipping step (S230), an upper surface of the epitaxial layer 2 may be bonded to the substrate and flipped.

In a layer removal step (S222), the first epitaxial layer 2-1 and the second epitaxial layer 2-2 of the epitaxial layer 2 may be removed. In the layer removal step (S222), the first epitaxial layer 2-1 and the second epitaxial layer 2-2 of the epitaxial layer 2 can be removed by mechanical etching or chemical etching. When the first epitaxial layer 2-1 and the second epitaxial layer 2-2 of the epitaxial layer 2 are removed in the layer removal step (S220), only the quantum dot layer 2-6 in which the quantum dot, which is the single emitter 300, is located may remain in the epitaxial layer 2.

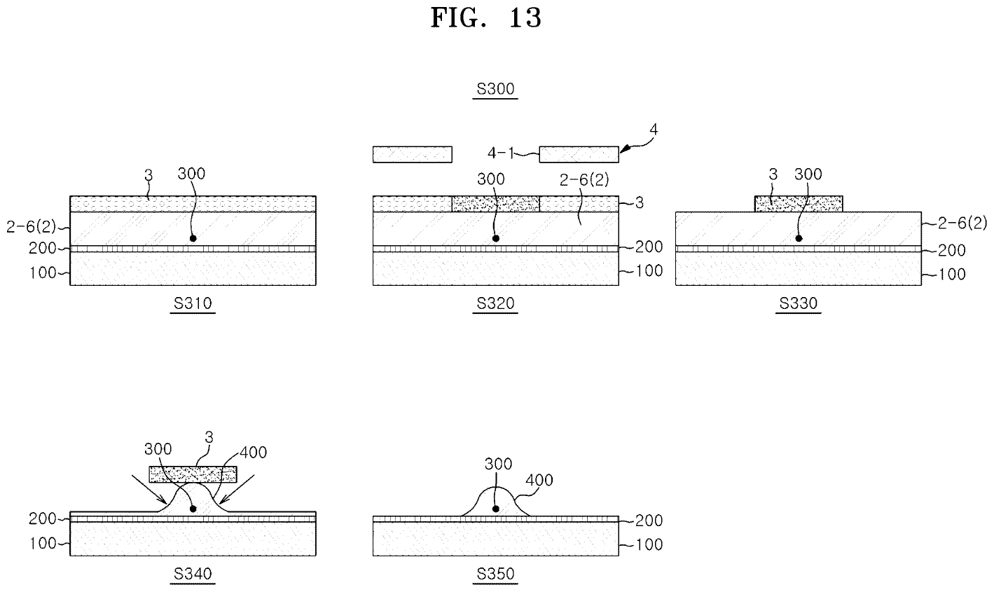

Referring to FIG. 13, in the first solid immersion lens forming step (S300), the portion of the epitaxial layer 2 where the quantum dot, which is the single emitter 300, is located is used to form, on the insulating layer 200, the first solid immersion lens portion 400 surrounding the quantum dot, which is the single emitter 300. In other words, in the first solid immersion lens forming step (S300), the first solid immersion lens portion 400 surrounding the quantum dot which is the single emitter 300 may be formed on the insulating layer 200 using the quantum dot layer 2-6 of the epitaxial layer 2, in which the quantum dot which is the single emitter 300 is located. The first solid immersion lens forming step S300 includes a first photoresist coating step S310, a first exposure step S320, a first developing step S330, an etching step S340, and a first photoresist removal step S350.

In the first photoresist coating step (S310), the first photoresist 3 may be coated on the quantum dot layer 2-6 of the epitaxial layer 2. The first photoresist 3 may be a negative photoresist. The negative photoresist may be AZ5214, S1818, or SU-8, but other negative photoresists may also be used.

In the first exposure step S320, laser exposure may be performed on the first photoresist 3 using the first photo mask 4 on which the first pattern 4-1 is formed. For example, when the first photoresist 3 is a negative photoresist, laser exposure may be performed on a portion of the first photoresist 3 above a portion of the quantum dot layer 2-6 that becomes the first solid immersion lens portion 400, by using the first photo mask 4. In this case, the position of the quantum dot which is the single emitter 300 in the first solid immersion lens portion 400 can be accurately found using the laser, and this position can be utilized for disposition of the first photo mask 4, laser exposure, or the like. In other words, when the quantum dot which is the single emitter 300 is irradiated with a laser, the position of the quantum dot, which is a single emitter 300, can be accurately found by using the emission of the single photons from the quantum dot. Further, the first photo mask 4 may be disposed so that the quantum dot, which is the single emitter 300, is located at an exact center of the first pattern 4-1 of the first photo mask 4. In this state, laser exposure of the first photoresist 3 can be performed.

Meanwhile, in the first exposure step (S320), laser exposure can be performed on the first photoresist 3 using a focusing laser without using the first photo mask 4. In this case, the laser itself can serve as a circular mask. For example, when the first photoresist 3 is a negative photoresist, the laser exposure can be performed by placing a laser spot on the portion of the first photoresist 3 above the portion of the quantum dot layer 2-6 that will become the first solid immersion lens portion 400 and irradiating a strong laser thereto. In this case, the position of the quantum dot which is the single emitter 300 in the first solid immersion lens portion 400 can be accurately found using the laser, and this position can be utilized for laser exposure, or the like. In other words, when the quantum dot which is the single emitter 300 is irradiated with a laser, the position of the quantum dot can be accurately found by using the emission of the single photons from the quantum dot. Further, the laser can be located so that the quantum dot is located at an exact center of the laser spot. In this state, laser exposure of the first photoresist 3 can be performed.

In the first development step (S330), a portion of the first photoresist 3 other than the portion of the first photoresist 3 on the portion of the quantum dot layer 2-6, which will become the first solid immersion lens portion 400, may be removed using a developer. Representative developers include an AZ 300 MIF developer, an AZ 500 MIF developer, a SU-8 developer, and an MF-319 developer sold by photoresist development companies, and other developers may also be available. In the etching step (S340), the quantum dot layer 2-6 under the remaining first photoresist 3 is etched so that the first solid immersion lens portion 400 can be formed. In the etching step (S340), the quantum dot layer 2-6 under the first photoresist 3 is etched by wet etching so that the first solid immersion lens portion 400 can be formed. In the wet etching, a mixed solution of hydrochloric acid (HCl) and hydrogen peroxide (H2O2), a mixed solution of sulfuric acid (H2SO4) and hydrogen peroxide, or a mixed solution of phosphoric acid (H3PO4), nitric acid (HNO3), citric acid (C6H8O7) and hydrogen peroxide may be available.

In the first photoresist removal step (S350), the remaining first photoresist 3 may be removed. In the first photoresist removal step (S350), the remaining first photoresist 3 may be removed by using a material capable of removing organic solvents, such as acetone.

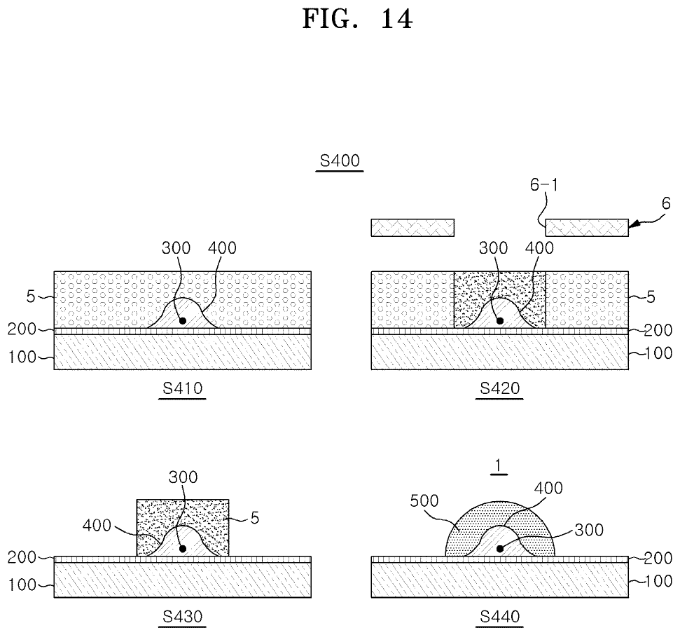

Referring to FIG. 14, in the forming the second solid immersion lens portion (S400), the second solid immersion lens portion 500 surrounding the first solid immersion lens portion 400 may be formed on the insulating layer 200. The forming the second solid immersion lens (S400) may include a second photoresist coating step (S410), a second exposure step (S420), a second developing step (S430), and a reflow step (S440).

In the second photoresist coating step (S410), the second photoresist 5 may be coated on the insulating layer 200 to cover the first solid immersion lens portion 400. The second photoresist 5 may be a negative photoresist.

In the second exposure step (S420), laser exposure may be performed on the second photoresist 5 using a second photo mask 6 on which a second pattern 6-1 is formed. For example, when the second photoresist 5 is the negative photoresist, laser exposure is performed on a portion of the second photoresist 5 that becomes the second solid immersion lens portion 500 by using the second photo mask 6. In this case, the position of the quantum dot which is the single emitter 300 in the first solid immersion lens portion 400 can be accurately found using the laser, and this position can be utilized for disposition of the second photo mask 6, laser exposure, or the like. In other words, when the quantum dot which is the single emitter 300 is irradiated with a laser, the position of the quantum dot, which is a single emitter 300, can be accurately found by using the emission of the single photons from the quantum dot. Further, the second photo mask 6 may be disposed so that the quantum dot is located at an exact center of the second pattern 6-1 of the second photo mask 6. In this way, laser exposure of the second photoresist 5 may be performed. In this process, the center of the cross section of the second solid immersion lens portion 500 on the insulating layer 200 can be matched with the center of the cross section of the first solid immersion lens portion 400 on the insulating layer 200.

Meanwhile, in the second exposure step (S420), the laser exposure may be performed on the second photoresist 5 using a focusing laser without using the second photo mask 6. In this case, the laser itself can serve as a circular mask. For example, when the second photoresist 5 is the negative photoresist, the laser exposure may be performed on the laser spot of the second photoresist 5 that becomes the second solid immersion lens portion 500. In this case, the position of the quantum dot which is the single emitter 300 in the first solid immersion lens portion 400 can be accurately found using the laser, and this position can be utilized for disposition of the second photo mask 6, laser exposure, or the like. In other words, when the quantum dot which is the single emitter 300 is irradiated with a laser, the position of the quantum dot can be accurately found by using the emission of the single photons from the quantum dot. Further, the laser can be located so that the quantum dot, which is the single emitter 300, is located at the exact center of the laser spot. In this state, laser exposure of the second photoresist 5 can be performed.

In the second development step (S430), a portion of the second photoresist 5 other than the portion of the second photoresist 5 that will become the second solid immersion lens portion 500 may be removed by using a developer. Representative developers available for photoresist may include an AZ 300 MIF developer, an AZ 500 MIF developer, a SU-8 developer, and an MF-319 developer sold by photoresist development companies, and other developers may also be available.

In the reflow step (S440), heat is applied to the remaining second photoresist 5 for fluidity so that the remaining second photoresist 5 becomes the second solid immersion lens portion 500.

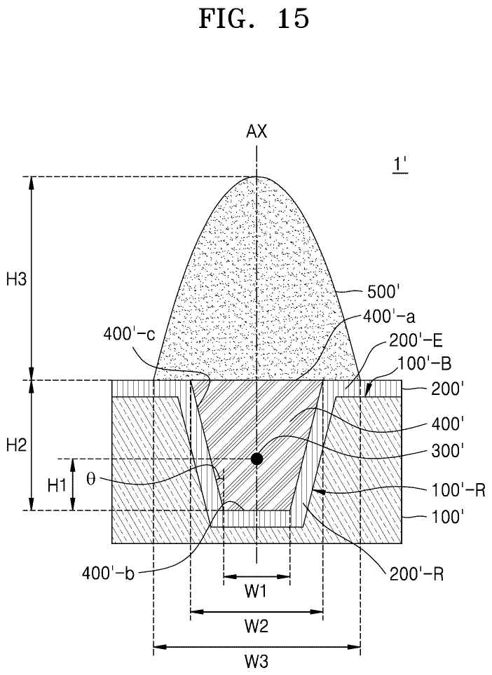

Hereinafter, a specific configuration of a single photon source device 1′ according to a third embodiment of the present disclosure will be described with reference to FIGS. 15 to 17.

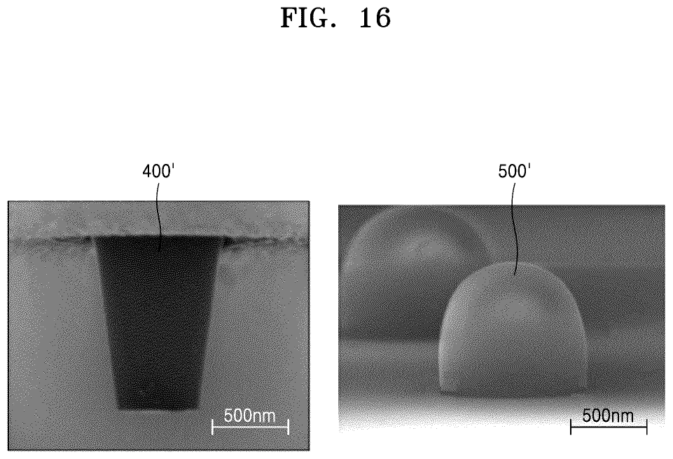

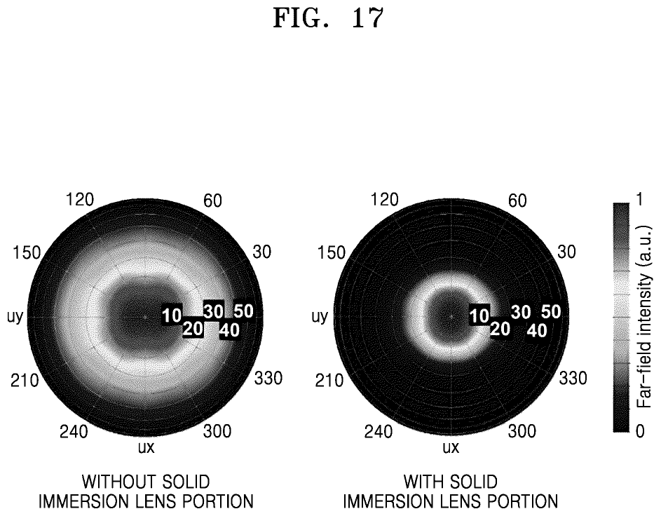

FIG. 15 is a cross-sectional view of the single photon source device 1′ according to the third embodiment of the present disclosure, and FIG. 16 is an image obtained by imaging a solid resonator 400′ and a solid immersion lens portion 500′ of the single photon source device 1′ according to the third embodiment of the present disclosure by using a scanning electron microscope. FIG. 17 is a graph showing a far-field electric field intensity distribution of a single photon source device that does not include the solid immersion lens portion 500′ and a far-field electric field intensity distribution of a single photon source device that includes the solid immersion lens portion 500′.

Referring to FIG. 15, the single photon source device 1′ may include a reflection layer 100′, an insulating layer 200′, a single emitter 300′, a solid resonator 400′, and the solid immersion lens portion 500′. The single photon source device 1′ according to the embodiment illustrated in FIG. 15 differs from the single photon source device 1 according to the embodiment described with reference to FIG. 1 in the structure and arrangement of the reflection layer 100′, the insulating layer 200′, and the solid resonator 400′, and the solid immersion lens portion 500′ may correspond to the solid immersion lens portion 500. Therefore, the following description will focus on the difference described above.

The reflection layer 100′ may include a base portion 100′-B and a recessed portion 100′-R having a concave shape that is recessed from the base portion 100′-B. The base portion 100′-B may correspond to the surface of the reflection layer 100′ on which the recessed portion 100′-R is not formed.

The recessed portion 100′-R may be formed to accommodate the single emitter 300′. Specifically, the recessed portion 100′-R may be formed at a position corresponding to the single emitter 300′ and may have a shape that is recessed toward the single emitter 300′.

In an embodiment, the recessed portion 100′-R may have a shape in which the width decreases as the distance from the base portion 100′-B increases in the height direction of the single photon source device 1′. Here, the width of the recessed portion 100′-R may be defined as a diameter of a cross section parallel to the base portion 100′-B. That is, the recessed portion 100′-R may have a shape in which the diameter decreases downward. A longitudinal cross section of the recessed portion 100′-R may have a trapezoidal shape in which the lower width is less than the upper width.

Since the reflection layer 100′ includes the recessed portion 100′-R that accommodates the single emitter 300′, the reflection layer 100′ may reflect the single photon emitted from the single emitter 300′ and traveling into the interior of the recessed portion 100′-R and may provide the single photon in the emission direction of the single photon source device 1′. The recessed portion 100′-R may provide a reflection surface surrounding the single emitter 300′ and inclined with respect to the height direction of the single photon source device 1′. Due to the recessed portion 100′-R, the single photon emitted from the single emitter 300′ may be collected with a concentrated direction in the height direction of the single photon source device 1′.

The insulating layer 200′ may be disposed on the reflection layer 100′. The insulating layer 200′ may be disposed along the surface of the reflection layer 100′ including the recessed portion 100′-R. The insulating layer 200′ may include a recessed-portion corresponding portion 200′-R covering the recessed portion 100′-R of the reflection layer 100′, and an extension portion 200′-E extending from an edge of the recessed portion 100′-R. The extension portion 200′-E may extend parallel to the base portion 100′-B.

The insulating layer 200′ may be disposed between the reflection layer 100′ and the solid resonator 400′ to insulate the reflection layer 100′ and the solid resonator 400′ from each other. The insulating layer 200′ may minimize the influence of resistance loss caused by the reflection layer 100′ on the single emitter 300′, and may enable the single photon to be efficiently emitted from the single emitter 300′ without being influenced by the reflection layer 100′.

The insulating layer 200′ may be transparent at an emission wavelength of the single emitter 300′. Therefore, the single photon emitted from the single emitter 300′ and traveling toward the reflection layer 100′ may pass through the insulating layer 200′ and reach the reflection layer 100′.

The single emitter 300′ that emits the single photon may be disposed within the recessed portion 100′-R of the reflection layer 100′. The single emitter 300′ may be surrounded by the solid resonator 400′ and may be spaced apart from the insulating layer 200′.

The single emitter 300′ may be spaced apart from the insulating layer 200′, which is disposed on the bottom surface of the recessed portion 100′-R, by a first distance H1 in the height direction of the single photon source device 1′. Here, the first distance H1 may be a distance corresponding to an antinode of a distribution of the single photon emitted from the single emitter 300′. With this configuration, most of the single photons emitted from the single emitter 300′ and the single photons emitted from the single emitter 300′ and reflected by the reflection layer 100′ may pass through the solid resonator 400′ and travel to the solid immersion lens portion 500′.

The single emitter 300′ may be disposed within a predetermined distance from a central axis AX of the solid resonator 400′. For example, the single emitter 300′ may be located within 200 nm from the central axis AX of the solid resonator 400′. When the single emitter 300′ is located outside 200 nm from the central axis AX of the solid resonator 400′, the emission efficiency of the single photon source device 1′ may be reduced.

The solid resonator 400′ may fill the recessed portion 100′-R of the reflection layer 100′ covered by the insulating layer 200′. The solid resonator 400′ may be disposed to surround the single emitter 300′ within the recessed portion 100′-R of the reflection layer 100′.

The solid resonator 400′ may have a shape corresponding to a shape of the recessed portion 100′-R. For example, the solid resonator 400′ may have a truncated conical shape, as illustrated in a drawing on the left side of FIG. 16. Specifically, the solid resonator 400′ may include a first surface 400′-a, a second surface 400′-b facing the first surface 400′-a, and a side surface 400′-c connecting the first surface 400′-a to the second surface 400′-b.

The first surface 400′-a of the solid resonator 400′ is a surface that is in direct contact with the solid immersion lens portion 500′ and may be located at the same height as one surface of the extension portion 200′-E of the insulating layer 200′. The first surface 400′-a of the solid resonator 400′ may have a larger area than the second surface 400′-b. In other words, an upper width W2 of the solid resonator 400′ may be greater than a lower width W1.

The lower width W1 of the solid resonator 400′ may be about 300 nm to about 2000 nm. The emission efficiency may be reduced when the lower width W1 of the solid resonator 400′ is less than 300 nm or greater than 2000 nm.

In an embodiment, a thickness, that is, a height H2, of the solid resonator 400′ may be greater than half of the lower width W1. When the height H2 of the solid resonator 400′ is greater than half of the lower width W1, the vertical orientation of the single photon is strengthened so that the light collection efficiency may be improved. However, the present disclosure is not limited thereto, and the height H2 of the solid resonator 400′ may have a value equal to or less than half of the lower width W1.

The height H2 of the solid resonator 400′ may be about 300 nm to 2000 nm. When the height H2 of the solid resonator 400′ is less than 300 nm or greater than 2000 nm, the emission efficiency of the solid resonator 400′ may be reduced.

The side surface 400′-c of the solid resonator 400′ may include a tapered inclined surface so that the diameter gradually decreases from the first surface 400′-a to the second surface 400′-b. A side inclination angle (θ) of the solid resonator 400′ may be about 8° to about 15°. Here, the side inclination angle (θ) of the solid resonator 400′ may refer to an angle formed by the side surface 400′-c of the solid resonator 400′ with respect to the central axis AX of the solid resonator 400′. When the side inclination angle (θ) of the solid resonator 400′ is less than about 8° or greater than about 15°, the light collection efficiency may be reduced.

A refractive index of the solid resonator 400′ may be about 1.8 to 4.0. When the refractive index of the solid resonator 400′ is less than 1.8, the emission efficiency may be reduced. In addition, when the refractive index of the solid resonator 400′ is greater than 4.0, there may be sensitivity to a manufacturing error.

The solid resonator 400′ may include a semiconductor. For example, the solid resonator 400′ may include one or more of gallium arsenide (GaAs), aluminum gallium arsenide (AlGaAs), gallium indium phosphide (GaInP), gallium phosphide (GaP), gallium nitride (GaN), indium gallium nitride (InGaN), aluminum gallium nitride (AlGaN), indium gallium arsenide (InGaAs), aluminum indium gallium arsenide (AlInGaAs), indium phosphide (InP), and indium gallium arsenide phosphide (InGaAsP). In a case where the single emitter 300′ is a quantum dot, the solid resonator 400′ may be formed by stacking several types of semiconductors to form a quantum dot and then dry-etching or wet-etching a layer where the quantum dot is located, as will be described later.

The single photon emitted from the single emitter 300′ and the single photon emitted from the single emitter 300′ and reflected by the reflection layer 100′ may pass through the solid resonator 400′ and travel to the solid immersion lens portion 500′. Further, the solid resonator 400′ may form an optical mode so that the single photon emitted from the single emitter 300′ and the single photon emitted from the single emitter 300′ and reflected by the reflection layer 100′ are primarily collected. Through the collection of the single photons in the solid resonator 400′, the single photon emitted from the single emitter 300′ and the single photon emitted from the single emitter 300′ and reflected by the reflection layer 100′ may be concentrated in the center portion of the solid resonator 400′ and travel to the solid immersion lens portion 500′.

Referring to a drawing on the left side of FIG. 17, it may be seen that the single photon emitted from the single emitter 300′ and the single photon emitted from the single emitter 300′ and reflected by the reflection layer 100′ may be collected in the central portion while traveling inside the solid resonator 400′. The single photon source device 1′ may collect the single photon emitted from the single emitter 300 to the central portion of the single photon source device 1′ through the solid resonator 400′ provided to fill the recessed portion 100′-R of the reflection layer 100′, and may emit the single photon in the height direction of the single photon source device 1′ with high efficiency.

The solid immersion lens portion 500′ may be disposed on the solid resonator 400′. The solid immersion lens portion 500′ may be disposed to surround the solid resonator 400′ exposed on the recessed portion 100′-R of the reflection layer 100′. Specifically, the solid immersion lens portion 500′ may be in direct contact with the first surface 400′-a, which is the upper surface of the solid resonator 400′, and may completely cover the first surface 400′-a of the solid resonator 400′.

The solid immersion lens portion 500′ may have a convex shape protruding from the first surface 400′-a of the solid resonator 400′. For example, the solid immersion lens portion 500′ may have a dome shape, as illustrated in a drawing on the right side of FIG. 16.

In an embodiment, a thickness, that is, a height H3, of the solid immersion lens portion 500′ may have a value greater than half of a width W3 of the lower surface. Since the height H3 of the solid immersion lens portion 500′ has a value greater than half of the width W3 of the lower surface, a beam divergence angle may decrease. However, the present disclosure is not limited thereto, and the height H3 of the solid immersion lens portion 500′ may have a value equal to or less than half of the width W3 of the lower surface.

For example, the width W3 of the lower surface of the solid immersion lens portion 500′ may be about 0.5 μm to 10 μm, and the height H3 may be about 0.25 μm to 10 μm. When the width W3 of the lower surface of the solid immersion lens portion 500′ is less than 0.5 μm or greater than 10 μm, the emission efficiency may be reduced. In addition, when the height H3 of the solid immersion lens portion 500′ is less than 0.25 μm or greater than 10 μm, the emission efficiency may be reduced.

In an embodiment, the width W3 of the lower surface of the solid immersion lens portion 500′ may be greater than the width W2 of the first surface 400′-a of the solid resonator 400′ in direct contact therewith.

The center of the cross section of the solid immersion lens portion 500′ on the solid resonator 400′ may be located within 500 nm in a radial direction from an extension line of a central axis VL′ of the solid resonator 400′. Therefore, most of the single photons emitted from the single emitter 300′ and the single photons emitted from the single emitter 300′ and reflected by the reflection layer 100′ may pass through the solid resonator 400′ and travel to the solid immersion lens portion 500′. When the center of the cross section of the solid immersion lens portion 500′ on the solid resonator 400′ is located at the radial distance greater than 500 nm from the extension line of the central axis VL′ of the solid resonator 400′, the emission efficiency may be reduced.

The solid immersion lens portion 500′ may include one or more of a polymer and a dielectric. The refractive index of the solid immersion lens portion 500′ may be about 1.2 to 2.5. When the refractive index of the solid immersion lens portion 500′ is less than 1.2 or greater than 2.5, vertical orientation adjustment may be difficult.

In an embodiment, the refractive index of the solid immersion lens portion 500′ may be less than the refractive index of the solid resonator 400′. Since the refractive index of the solid immersion lens portion 500′ is less than the refractive index of the solid immersion lens portion 500′, a light emission direction of the single photon may be directed in the height direction of the single photon source device 1′ without hardly changing the optical mode in the solid resonator 400′, and an operating bandwidth of the single emitter 300 may be widened.

The solid immersion lens portion 500′ may improve the directionality of the single photons that passed through the solid resonator 400′. Due to the improved directionality provided by the solid immersion lens portion 500′, most of the single photons may be emitted in the height direction of the single photon source device 1′ from the center of the single photon source device 1′. In other words, the single photons may be emitted with directionality from the center of the single photon source device 1′. Referring to a drawing on the right side of FIG. 17, it may be seen that the single photons are further collected to the center portion of the immersion lens portion 500′ and thus emitted in the height direction of the single photon source device 1′ from the solid immersion lens portion 500′.

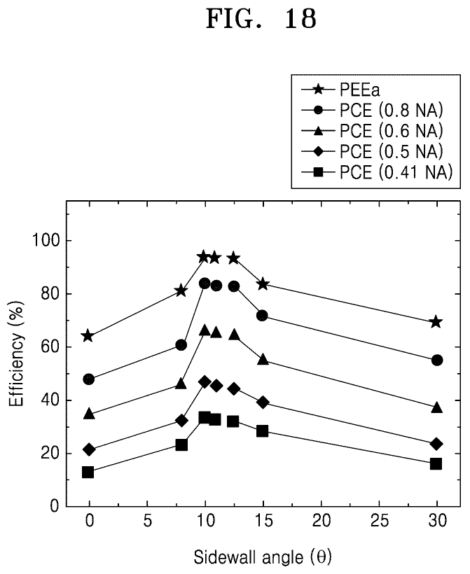

FIG. 18 is a graph showing light collection efficiency according to a side inclination angle (θ) of a solid resonator.

Referring to FIG. 18, it may be seen that the light collection efficiency of the solid resonator 400′ changes depending on the side inclination angle (θ). FIG. 18 shows change in light collection efficiency under various numerical aperture (NA) conditions. PFEa refers to photon extraction efficiency into the air, and PCE refers to photon collection efficiency at a specific NA.

When the side inclination angle (θ) is less than about 10°, the light collection efficiency of the solid resonator 400′ increases as the side inclination angle (θ) increases, and when the side inclination angle (θ) is greater than about 13°, the light collection efficiency of the solid resonator 400′ decreases as the side inclination angle (θ) increases. It may be seen that the solid resonator 400′ shows high light collection efficiency when the side inclination angle (θ) is in the range of about 8° to 15°, regardless of the NA, and in particular, shows maximum light collection efficiency when the side inclination angle (θ) is in the range of about 10° to 12.5°.

When the side inclination angle (θ) is about 10° to 12.5°, it may be seen that high light collection efficiency of 80% or more is shown under the condition that the NA is 0.8, and high light collection efficiency of about 45% is shown even under the condition that the NA is 0.5.

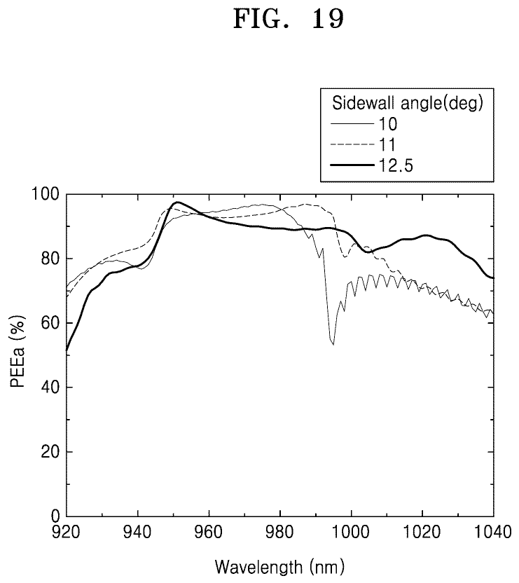

FIG. 19 is a graph showing photon extraction efficiency into air (PEEa) according to a wavelength at each side inclination angle (θ) of the solid resonator 400′.

Referring to FIG. 19, it may be seen that the solid resonator 400′ shows high light collection efficiency of up to 90% or more when the side inclination angle (θ) is 10°, 11°, or 12.5°, and shows stable performance in a wide wavelength band of about 920 nm to 1,040 nm.

In addition, it may be seen that an operating band of the single photon source device 1′ changes when the side inclination angle (θ) of the solid resonator 400′ changes to 12.5°, 11°, and 10°. Specifically, when the side inclination angle (θ) of the solid resonator 400′ is 12.5°, 80% or more of single photons are collected in a wavelength range of about 940 nm to 1,040 nm, and thus, a wide bandwidth of about 100 nm is provided. When the side inclination angle (θ) of the solid resonator 400′ is 11°, the light collection efficiency of single photons decreases in a wavelength range of about 990 nm or more, and when the side inclination angle (θ) is 10°, the light collection efficiency of single photons decreases rapidly in a wavelength range of about 980 nm or more. Therefore, it may be seen that as the side inclination angle (e) of the solid resonator 400′ becomes less than 12.5°, the wavelength range in which the collection of the single photons is reduced increases, and as a result, the operating band of the single photon source device 1′ decreases.

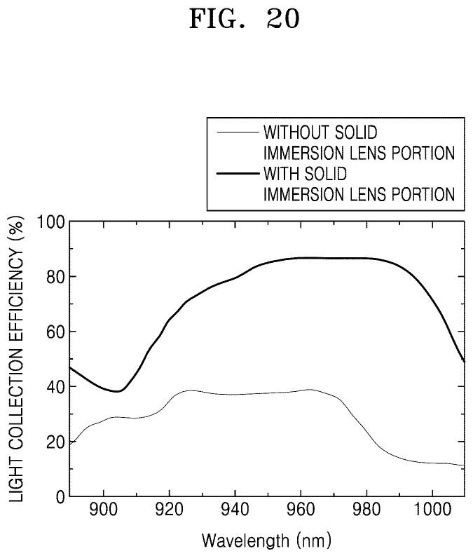

FIG. 20 is a graph showing light collection efficiency of a single photon source device that does not include the solid immersion lens portion 500′ and light collection efficiency of a single photon source device that includes the solid immersion lens portion 500′.

Referring to FIG. 20, it may be seen that the maximum light collection efficiency of the single photon source device 1′ increases from 40% to 88%, compared to a structure that does not include the solid immersion lens portion 500′. In other words, it may be seen that the brightness of the single photon source device 1′ increases by twice or more, compared to a structure that does not include the solid immersion lens portion 500′.

In addition, it may be seen that the single photon source device 1′ collects 80% or more of single photons in a wavelength range of about 940 nm to 1,000 nm. That is, it may be seen that the single photon source device 1′ collects 80% or more of photons in a bandwidth of about 60 nm. Therefore, the single photon source device 1′ may simultaneously satisfy a wide operating band and high light collection efficiency.

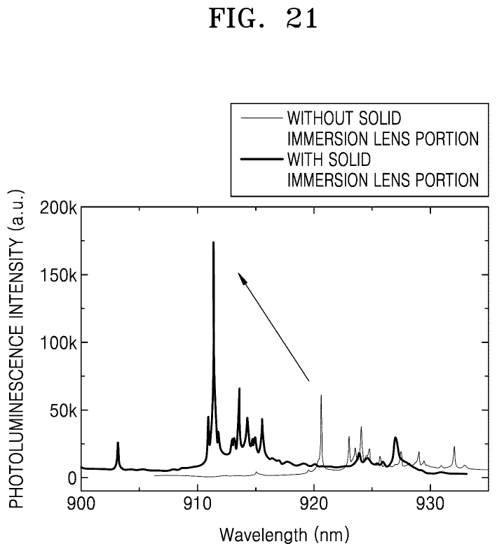

FIG. 21 is a graph showing single photon signal intensity of a single photon source device that does not include the solid immersion lens portion 500′ and single photon signal intensity of a single photon source device that includes the solid immersion lens portion 500′.

Referring to FIG. 21, it may be seen that, in the single photon source device 1′, the wavelength of the single photon emitted from the single emitter 300′ changes from about 920 nm to about 910 nm and the single photon signal intensity increases by about 2.4 times, compared to a structure that does not include the solid immersion lens portion 500′. It may be confirmed that the solid immersion lens portion 500′ serves to improve the light collection efficiency of the single photons and improve the spectral characteristics of the single photons. Since the single photon source device 1′ includes the solid resonator 400′ having a truncated conical structure and the solid immersion lens portion 500′, the single photon source device 1′ may enable stable single photon emission with high efficiency in a wide operating band and may improve the output direction of the single photons.

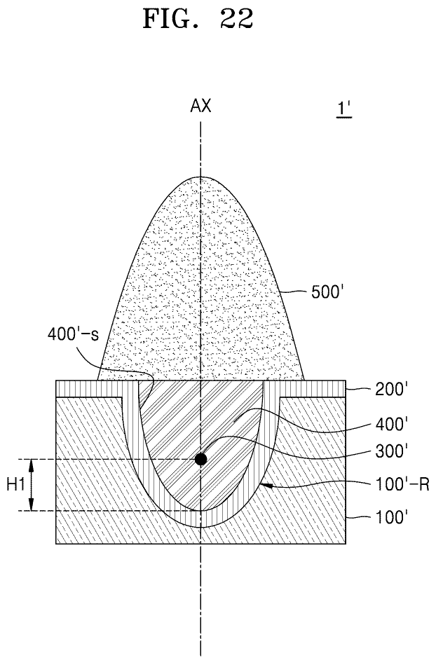

FIG. 22 is a cross-sectional view illustrating a modification of the single photon source device 1′ of FIG. 15. Since the modification of the single photon source device 1′ differs from the single photon source device 1′ described with reference to FIG. 15 in a structure of a reflection layer 100′ and a solid resonator 400′, the following description will focus on the differences, and the same description and reference numerals as those in the above-described embodiments will be used.

Referring to FIG. 22, the reflection layer 100′ may include a hemispherical or parabolic recessed portion 100′-R. An inner surface of the recessed portion 100′-R may include a curved surface. An insulating layer 200′ may be disposed along the surface of the reflection layer 100′ including the recessed portion 100′-R.

The solid resonator 400′ may be disposed on the insulating layer 200′ and may be disposed to fill the recessed portion 100′-R of the reflection layer 100′. The solid resonator 400′ may have a hemispherical or parabolic shape. A first surface 400′-s of the solid resonator 400′ facing the reflection layer 100′ may be formed as a curved surface having a curvature.

A single emitter 300′ may be disposed inside the solid resonator 400′. The single emitter 300′ may be disposed within a predetermined distance from a central axis AX of the solid resonator 400′. For example, the single emitter 300′ may be located within 200 nm from the central axis AX of the solid resonator 400′.

A height H1 of the single emitter 300′ inside the solid resonator 400′ may be controlled to optimize single photon emission of the single photon source device 1′. Here, the height H1 of the single emitter 300′ may be defined as the distance from the lowest point of the solid resonator 400′ in the height direction. In an embodiment, the height H1 of the single emitter 300′ may be set to a distance corresponding to an antinode of a distribution of the single photon.

The solid resonator 400′ may allow single photons emitted from the single emitter 300′ to be more efficiently collected to the central portion of the solid resonator 400′ by the first surface 400′-s having a curvature. Therefore, the optical coupling efficiency between the solid resonator 400′ and the solid immersion lens portion 500′ may be improved and the emission efficiency of the single photon source device 1′ may be improved.

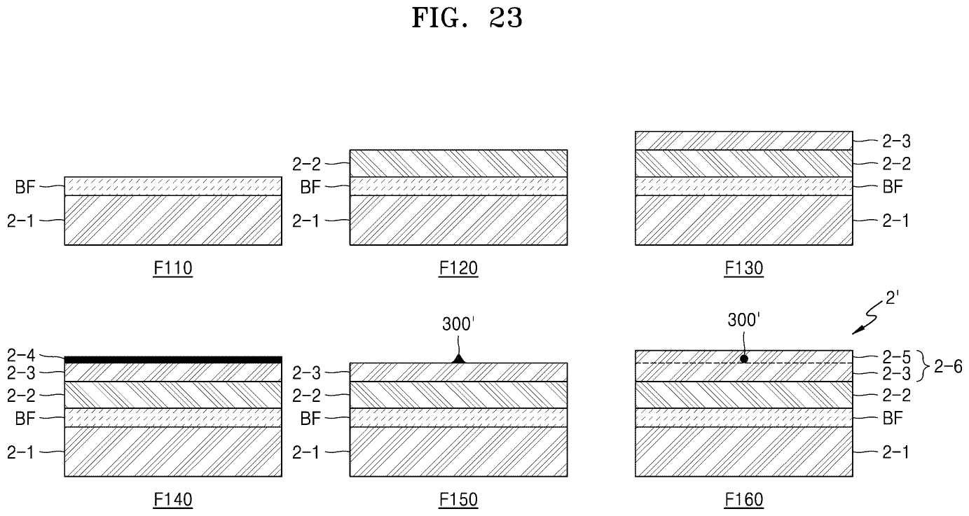

FIGS. 23 to 26 are diagrams describing a method of manufacturing the single photon source device 1′ of FIG. 15.

Referring to FIGS. 23 to 26, a method of manufacturing a single photon source device may include a quantum dot containing epitaxial layer forming step (F100), a solid resonator forming step (F200), a reflection layer forming step (F300), and a solid immersion lens portion forming step (F400).

In the quantum dot containing epitaxial layer forming step (F100), a quantum dot containing epitaxial layer 2′ in which a quantum dot is located may be formed as the single emitter 300′. As illustrated in FIG. 23, the quantum dot containing epitaxial layer forming step (F100) may include a first laminate layer preparing step (F110), a second laminate layer stacking step (F120), a third laminate layer stacking step (F130), a quantum dot forming layer stacking step (F140), a single emitter forming step (F150), and a quantum dot capping step (F160).

In the first laminate layer preparing step (F110), a first laminate layer 2-1 may be prepared. The first laminate layer 2-1 may be a substrate. For example, the first laminate layer 2-1 may include one or more of gallium arsenide, indium gallium arsenide, gallium indium phosphide, aluminum gallium arsenide, aluminum arsenide, and indium phosphide. In other words, the first laminate layer 2-1 may be a substrate including at least one of gallium arsenide, indium arsenide, indium gallium arsenide, aluminum arsenide, and indium phosphide.

A buffer layer BF may be stacked on the first laminate layer 2-1. For example, the buffer layer BF may include one or more of gallium arsenide, indium gallium arsenide, gallium indium phosphide, aluminum gallium arsenide, aluminum arsenide, and indium phosphide. The buffer layer BF may be omitted.

In the second laminate layer stacking step (F120), a second laminate layer 2-2 may be stacked on the first laminate layer 2-1. For example, the second laminate layer 2-2 may include one or more of aluminum arsenide, aluminum gallium arsenide, gallium arsenide, aluminum indium gallium arsenide (AlINGaAs), indium gallium arsenide, indium gallium phosphide (InGaP), and indium gallium arsenide phosphide.

The second laminate layer 2-2 may be stacked on the first laminate layer 2-1 by molecular-beam epitaxy or metal organic chemical vapor deposition. The second laminate layer 2-2 has a high bandgap and thus may serve as a barrier layer that prevents electrons and holes generated in the quantum dots from diffusing downward.

In the third laminate layer stacking step (F130), a third laminate layer 2-3 may be stacked on the second laminate layer 2-2. For example, the third laminate layer 2-2 may include one or more of gallium arsenide, indium arsenide, indium gallium arsenide, aluminum arsenide, indium gallium arsenide phosphide, aluminum indium gallium arsenide, and indium phosphide.

The third laminate layer 2-3 may be stacked on the second laminate layer 2-2 by molecular-beam epitaxy or metal organic chemical vapor deposition. The third laminate layer 2-3 serves as a buffer layer for forming quantum dot, and may improve the match between the quantum dot and the second laminate layer 2-2 and alleviate deformation.

In the quantum dot forming layer stacking step (F140), a quantum dot forming layer 2-4 may be stacked on the third laminate layer 2-3. The quantum dot forming layer 2-4 may include one or more of indium arsenide, indium gallium arsenide, gallium arsenide, indium gallium arsenide phosphide, and indium phosphide.

The quantum dot forming layer 2-4 may be stacked on the third laminate layer 2-3 by molecular-beam epitaxy or metal organic chemical vapor deposition. Since the quantum dot forming layer 2-4 has a lower bandgap than the second laminate layer 2-2 and the third laminate layer 2-3, the quantum dot forming layer 2-4 may form a quantum dot structure in which electrons and holes are confined.

In the single emitter forming step (F150), a quantum dot serving as the single emitter 300′ may be formed on the third laminate layer 2-3. The quantum dot may be spontaneously formed by the interaction of strain energy and surface energy due to interlayer lattice mismatch when the quantum dot forming layer 2-4 is stacked on the third laminate layer 2-3.

In the quantum dot capping step (F160), a quantum dot capping layer 2-5 may be stacked on the third laminate layer 2-3 so that the quantum dot, which is the single emitter 300′, may be capped by the quantum dot capping layer 2-5. For example, the quantum dot capping layer 2-5 may include one or more of gallium arsenide, indium arsenide, indium gallium arsenide, aluminum arsenide, indium gallium arsenide phosphide, and indium phosphide.

The quantum dot capping layer 2-5 may be stacked on the third laminate layer 2-3 by molecular-beam epitaxy or metal organic chemical vapor deposition. The quantum dot capping layer 2-5 may protect the quantum dot, which is the single emitter 300′, from the outside. In addition, the third laminate layer 2-3 and the quantum dot capping layer 2-5 may be combined to form a quantum dot layer 2-6 in which the quantum dot, which is the single emitter 300′, is located. In addition, the thickness of the quantum dot capping layer 2-5 may be adjusted so that a first distance H1, which is a distance between the quantum dot, which is the single emitter 300′, and the insulating layer 200′, may be adjusted.

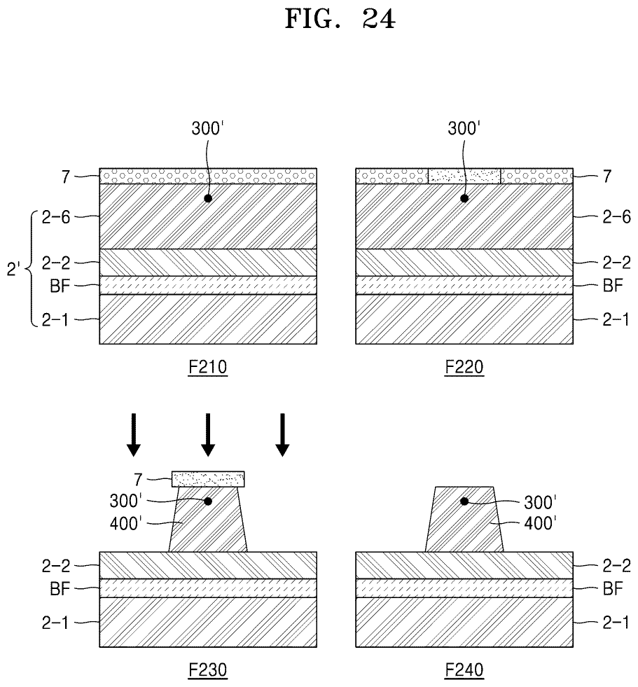

In the solid resonator forming step (F200), a solid resonator 400′ surrounding the single emitter 300′ may be formed by removing a portion of the quantum dot layer 2-6 in which the quantum dot, which is the single emitter 300′, is located. As illustrated in FIG. 24, the solid resonator forming step (F200) may include a first resist coating step (F210), a patterning step (F220), an etching step (F230), and a first resist removing step (F240).

In the first resist coating step F210, a first resist 7 may be coated on the quantum dot layer 2-6 of the quantum dot laminate 2′. The first resist 7 may be a negative resist for electron beam lithography or photolithography, but the present disclosure is not limited thereto.

In the patterning step (F220), a pattern corresponding to an area where the solid resonator 400′ is to be formed may be formed in the first resist 7. For example, in the patterning step (F220), a precise pattern may be formed directly on the first resist 7 by using electron beam lithography or photolithography. The patterned first resist 7 may be formed by selectively removing a peripheral portion of the first resist 7, except for the area where the solid resonator 400′ is to be formed, through a development process.

In the etching step (F230), the quantum dot layer 2-6 may be selectively etched by using the developed first resist 7 as a mask. For example, the quantum dot layer 2-6 may be removed through dry etching such as chemically assisted ion beam etching (CAIBE) or inductively coupled plasma reactive ion etching (ICPRIE). The CAIBE and ICPRIE is a dry etching method in which physical sputtering is combined with chemical reaction, and allows precise control of a side angle (θ) of the solid resonator 400′.

In the first resist removing step (F240), the remaining first resist 7 may be removed. The first resist 7 may be completely removed by using an organic solvent, such as acetone, or plasma ashing. In this manner, the shape of the solid resonator 400′ may be manufactured.

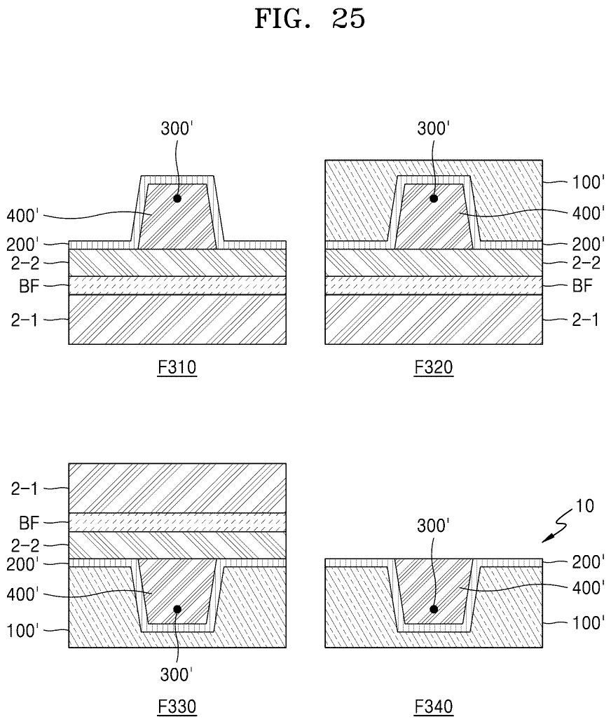

In the reflection layer forming step (F300), an insulating layer 200′ and a reflection layer 100′ may be sequentially stacked on the quantum dot containing epitaxial layer 2′ in which the solid resonator 400′ is formed. As illustrated in FIG. 25, the reflection layer forming step (F300) may include an insulating layer stacking step (F310), a reflection layer stacking step (F320), a flipping step (F330), and a layer removing step (F340).

In the insulating layer stacking step (F310), an insulating layer 200′ may be stacked to cover the second laminate layer 2-2 and the solid resonator 400′ protruding from the second laminate layer 2-2. For example, the insulating layer 200′ may include one or more of silicon nitride, silicon oxide, aluminum oxide, aluminum nitride, titanium oxide, hafnium oxide, and zirconium oxide. The insulating layer 200′ may be stacked by sputtering, electron beam deposition, atomic layer deposition or plasma-enhanced chemical vapor deposition.

In the reflection layer stacking step (F320), a reflection layer 100′ may be stacked on the insulating layer 200′. A recessed portion 100′-R may be formed in the reflection layer 100′ by the solid resonator 400′ protruding from the second laminate layer 2-2. For example, the reflection layer 100′ may include one or more of gold, silver, aluminum, copper, and a distributed Bragg reflector. The reflection layer 100′ may be stacked on the insulating layer 200′ by sputtering or electron beam deposition.

In the flipping step (F330), the quantum dot containing epitaxial layer 2′ may be flipped so that the reflection layer 100′ is located below the solid resonator 400′ and the insulating layer 200′. In the flipping step (F330), a substrate may be bonded on the reflection layer 100′ and flipped.

In the layer removing step (F340), the first laminate layer 2-1, the buffer layer BF, and the second laminate layer 2-2 of the quantum dot containing epitaxial layer 2′ may be removed. In the layer removing step (F340), the first laminate layer 2-1, the buffer layer BF, and the second laminate layer 2-2 of the quantum dot containing epitaxial layer 2′ may be removed by mechanical etching or chemical etching. By removing the first laminate layer 2-1, the buffer layer BF, and the second laminate layer 2-2, only the solid resonator 400′ in which the quantum dot, which is the single emitter 300′, is located may remain in the quantum dot containing epitaxial layer 2′.

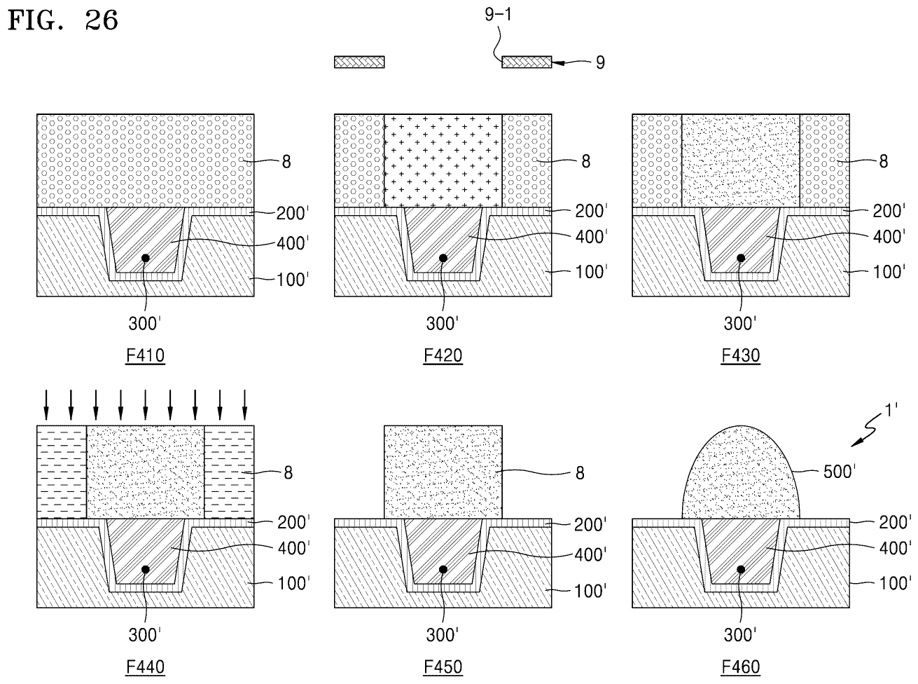

In the solid immersion lens portion forming step (F400), a solid immersion lens portion 500′ may be formed on the solid resonator 400′. As illustrated in FIG. 26, the solid immersion lens portion forming step (F400) may include a second resist coating step (F410), a first exposure step (F420), a heat treatment step (F430), a second exposure step (F440), a development step (F450), and a reflow step (F460).

In the second resist coating step (F410), a second resist 8 may be coated on the insulating layer 200 to cover the first solid immersion lens portion 400. For example, the second resist 8 may be a negative photoresist, but the present disclosure is not limited thereto.

In the first exposure step (F420), laser exposure may be performed on the second resist 8 by using a mask 9 on which a pattern 9-1 is formed. For example, when the second resist 8 is a negative photoresist, laser exposure may be performed by using the mask 9 on a portion of the second resist 8 that is to be the solid immersion lens portion 500′. At this time, the mask 9 may be disposed so that the quantum dot of the single emitter 300′ is located at an exact center of the pattern 9-1, and laser exposure may be performed so that a central axis of the solid immersion lens portion 500′ is matched with a central axis of the solid resonator 400′.

In the heat treatment step (F430), an exposed portion of the second resist 8 may be chemically stabilized by heat-treating the second resist 8 exposed through the first exposure step (F420). In this manner, the exposed portion of the second resist 8 may be transformed to be insoluble during development.

In the second exposure step (F440), full-surface exposure may be performed on the entire surface of the second resist 8 after the heat treatment. In this manner, a portion that is not exposed in the first exposure step (F420) may be transformed to have the property of dissolving during development.

In the developing step (F450), the second resist 8 except for the portion to be the solid immersion lens portion 500′ may be removed by using a developing solution. In the reflow step (F460), fluidity is imparted by applying heat to the remaining second resist 8 so that the remaining second resist 8 is made into the solid immersion lens portion 500′. The heated second resist 8 has a hemispherical or dome shape due to surface tension, and the curvature or height of the solid immersion lens portion 500′ may be controlled by adjusting a temperature and a time at which the second resist 8 is heated.

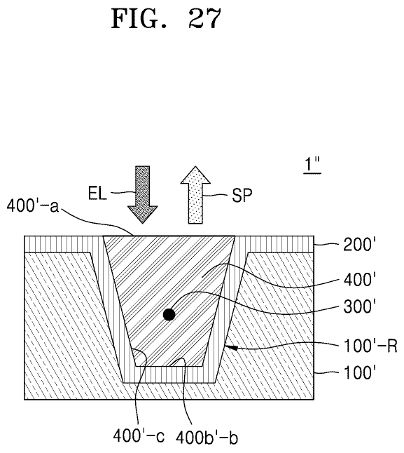

Hereinafter, a single photon source device 1″ according to a fourth embodiment of the present disclosure will be described with reference to FIGS. 27 to 29.

FIG. 27 is a cross-sectional view of the single photon source device 1″ according to the fourth embodiment of the present disclosure.

Referring to FIG. 27, the single photon source device 1″ may include a reflection layer 100′, an insulating layer 200′, a single emitter 300′, and a solid resonator 400′. The single photon source device 1″ according to the embodiment illustrated in FIG. 27 differs from the single photon source device 1′ according to the embodiment illustrated in FIG. 15 in that the single photon source device 1″ does not include the solid immersion lens portion 500′. Hereinafter, this difference will be mainly described, and the same description and reference numerals as those in the above-described embodiments will be used.

The single photon source device 1″ may emit single photons SP from a first surface 400′-a of the solid resonator 400′ through excitation light EL incident on the first surface 400′-a of the solid resonator 400′. The excitation light EL may excite the single emitter 300′ inside the solid resonator 400′, and the excited single emitter 300′ may emit the single photons SP through exciton recombination. The single photons emitted from the single emitter 300′ may be reflected from a recessed portion 100′-R of a reflection layer 100′ and collected upward, and may be collected toward the central portion of the solid resonator 400′ by a tapered structure of the solid resonator 400′ and emitted through the first surface 400′-a.

Since the single photon source device 1″ has a simple structure, the manufacturing process may be facilitated and the manufacturing cost may be reduced. Since the single photon source device 1″ may achieve high light collection efficiency with only the structure of the recessed portion 100′-R of the reflection layer 100′ and the solid resonator 400′, the single photon source device with excellent cost-effectiveness may be implemented. The single photon source device 1″ may be easily miniaturized and integrated, and thus may be applied to various quantum devices or quantum optical systems.

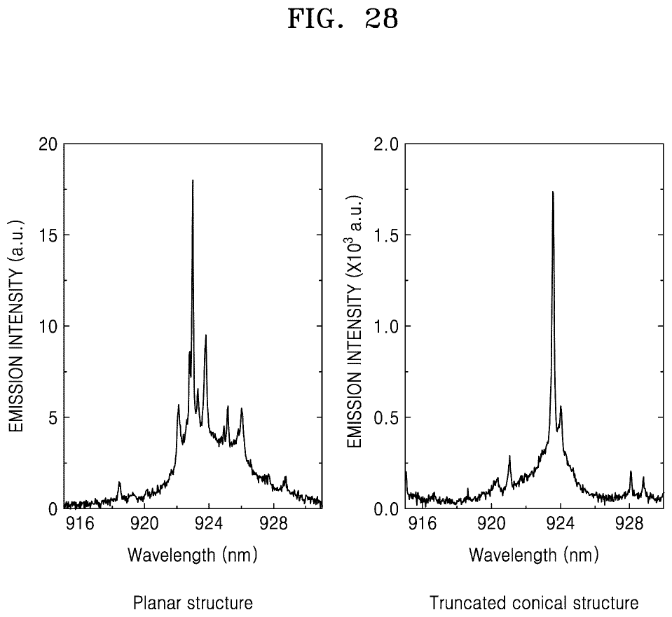

A graph on the left side of FIG. 28 is a graph showing emission intensity according to a wavelength in a single photon source device according to a comparative example, and a graph on the right side of FIG. 28 is a graph showing emission intensity according to a wavelength in the single photon source device 1″ according to the fourth embodiment of the present disclosure. In the single photon source device according to the comparative example, a reflection layer and a first solid immersion lens portion have a planar structure.

Referring to FIG. 28, it may be seen that emission intensity of the single photon source device 1″ increases by about 95 times, compared to the single photon source device according to the comparative example. In addition, it may be seen that the single photon source device 1″ shows a more distinct emission peak around 924 nm, compared to the single photon source device according to the comparative example, and the spectral purity of the single photon is improved.

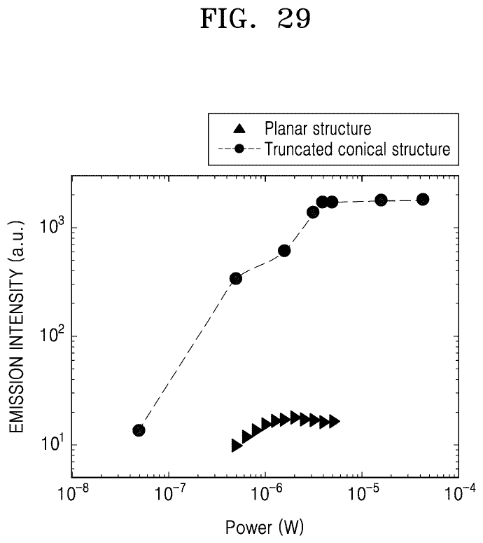

FIG. 29 is a graph showing emission intensity according to power of excitation light in the single photon source device according to the comparative example and the single photon source device 1″ according to the fourth embodiment of the present disclosure. In the single photon source device according to the comparative example, a reflection layer and a first solid immersion lens portion have a planar structure.

Referring to FIG. 29, it may be seen that the single photon source device 1″ shows improved emission intensity in all excitation light power ranges, compared to the single photon source device according to the comparative example. In addition, it may be seen that the single photon source device 1″ stably emits single photons even in an area where power of the excitation light is low, compared to the single photon source device according to the comparative example.

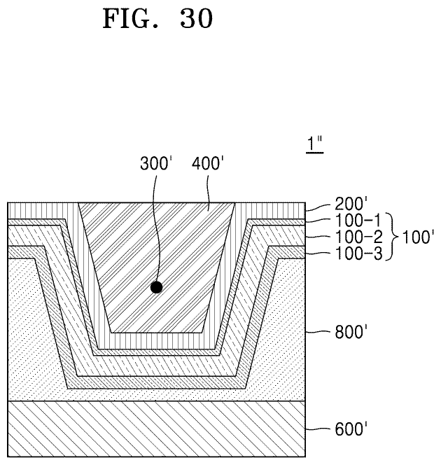

FIG. 30 is a cross-sectional view of a single photon source device 1″ according to a fifth embodiment of the present disclosure.

Referring to FIG. 30, the single photon source device 1′″ may include a reflection layer 100′, an insulating layer 200′, a single emitter 300′, a solid resonator 400′, a substrate 600′, and an adhesive layer 800′. The single photon source device 1′″ according to the embodiment illustrated in FIG. 30 differs from the single photon source device 1″ according to the embodiment illustrated in FIG. 27 in the structure of the reflection layer 100′ and in that the single photon source device 1″ further includes the substrate 600′ and the adhesive layer 800′. Hereinafter, this difference will be mainly described, and the same description and reference numerals as those in the above-described embodiments will be used.

The substrate 600′ may support the reflection layer 100′. The substrate 600′ may be bonded to the reflection layer 100′ by the adhesive layer 800′. For example, the substrate 600′ may include one or more of silicon, gallium arsenide, indium phosphide, aluminum arsenide, silicon oxide, aluminum oxide, and silicon nitride. For example, the adhesive layer 800′ may include epoxy, benzocyclobutene, polyimide, or the like.

The reflection layer 100′ may be disposed on the substrate 600′. In an embodiment, the reflection layer 100′ may be formed conformally along the shape of the solid resonator 400′. That is, the reflection layer 100′ may be disposed with a substantially uniform thickness on the lower surface and side surface of the solid resonator 400′.

The reflection layer 100′ may have a multilayer structure. For example, the reflection layer 100′ may have a structure in which a first metal layer 100′-1, a second metal layer 100′-2, and a third metal layer 100′-3 are sequentially stacked. The first metal layer 100′-1 may be in contact with the insulating layer 200′, and the third metal layer 100′-3 may be in contact with the substrate 600′ or the adhesive layer 800′.

The second metal layer 100′-2 may include a metal material having a higher reflectivity than the first metal layer 100′-1 and the third metal layer 100′-3. For example, the second metal layer 100′-2 may include gold (Au), silver (Ag), aluminum (Al), or platinum (Pt).

The first metal layer 100′-1 and the third metal layer 100′-3 may serve to protect the second metal layer 100′-2 and improve adhesive strength between layers adjacent to the reflection layer 100′. For example, the first metal layer 100′-1 and the third metal layer 100′-3 may include chromium (Cr), titanium (Ti), nickel (Ni), or an alloy thereof.

The examples of the present disclosure have been described above as specific embodiments, but these are only examples, and the present disclosure is not limited thereto, and should be construed as having the widest scope according to the technical spirit disclosed in the present specification. A person skilled in the art may combine/substitute the disclosed embodiments to implement a pattern of a shape that is not disclosed, but it also does not depart from the scope of the present disclosure. In addition, those skilled in the art can easily change or modify the disclosed embodiments based on the present specification, and it is clear that such changes or modifications also belong to the scope of the present disclosure.

What is claimed is:

1. A single photon source device comprising:
a reflection layer including a base portion and a recessed portion having a concave shape that is recessed from the base portion;
a single emitter disposed within the recessed portion of the reflection layer and configured to emit a single photon;
a solid resonator configured to fill the recessed portion to surround the single emitter; and
a solid immersion lens portion disposed on the solid resonator to surround the solid resonator.

2. The single photon source device of claim 1, further comprising an insulating layer disposed between the reflection layer and the solid resonator.

3. The single photon source device of claim 2, wherein the insulating layer is transparent at an emission wavelength of the single emitter.

4. The single photon source device of claim 2, wherein the insulating layer includes an extension portion extending parallel to the base portion from an edge of the recessed portion.

5. The single photon source device of claim 4, wherein one surface of the solid resonator is located at a same height as one surface of the extension portion.

6. The single photon source device of claim 1, wherein a width of the recessed portion gradually decreases as a distance from the base portion of the reflection layer increases.

7. The single photon source device of claim 6, wherein a cross section of the recessed portion perpendicular to the base portion has a trapezoidal shape or a parabolic shape.

8. The single photon source device of claim 1, wherein the solid resonator includes a first surface in direct contact with the solid immersion lens portion, a second surface facing the first surface, and a side surface between the first surface and the second surface, and
the side surface of the solid resonator includes a tapered inclined surface.

9. The single photon source device of claim 8, wherein the side surface of the solid resonator has an inclination angle of 8° to 15° with respect to a line parallel to a central axis of the solid resonator.

10. The single photon source device of claim 8, wherein the single emitter is spaced apart from the second surface of the solid resonator in a height direction of the single photon source device.

11. The single photon source device of claim 8, wherein a distance between the single emitter and the second surface of the solid resonator is a distance corresponding to an antinode of a distribution of the single photon emitted from the single emitter.

12. The single photon source device of claim 1, wherein the single emitter is located within 200 nm from a central axis of the solid resonator.

13. The single photon source device of claim 1, wherein the solid immersion lens portion has a convex shape protruding from one surface of the solid resonator.

14. The single photon source device of claim 1, wherein a center of a cross section of the solid immersion lens portion on the solid resonator is located within 500 nm from a virtual line extending from a central axis of the solid resonator.

15. The single photon source device of claim 1, wherein a maximum diameter of the solid immersion lens portion is greater than a maximum diameter of the solid resonator.

16. The single photon source device of claim 1, wherein a refractive index of the solid immersion lens portion is smaller than a refractive index of the solid resonator.

17. The single photon source device of claim 1, wherein the single emitter is a quantum dot.

18. The single photon source device of claim 17, wherein the quantum dot includes one or more of indium arsenide (InAs), indium gallium arsenide (InGaAs), aluminum gallium arsenide (AlGaAs), gallium arsenide (GaAs), and indium phosphide (InP).

19. A method of manufacturing a single photon source device, the method comprising:
a quantum dot containing epitaxial layer forming step of forming a quantum dot containing epitaxial layer in which a quantum dot is located;
a solid resonator forming step of forming a solid resonator surrounding the quantum dot by removing a portion of the quantum dot containing epitaxial layer;
a reflection layer forming step of forming, on the solid resonator, a reflection layer in which a recessed portion corresponding to the solid resonator is formed; and
a solid immersion lens portion forming step of forming a solid immersion lens portion facing the reflection layer on the solid resonator.
